(19) United States
(12) Patent Application Publication
(10) Pub. No.: US 2011/0221470 A1
(43) Pub. Date: Sep. 15, 2011

(54) MAGNETIC DEVICE FOR PERFORMING A "LOGIC FUNCTION"

(75) Inventors: Virgile Javerliac, St. Prim (FR); Guillaume Prenat, Grenoble (FR)

(73) Assignees: Commissariat a l'energie atomique et aux energies alternatives, F-75015 Paris (FR); Centre national de la recherche scientifique, F-75794 Paris Cedex 6 (FR)

(21) Appl. No.: 12/988,290

(22) PCT Filed: Apr. 15, 2009
(86) PCT No.: PCT/FR09/50690

§ 371 Date: May 23, 2011

(30) Foreign Application Priority Data
Apr. 16, 2008 (FR) 0852574

(51) Int. Cl. H03K 19/18

(52) U.S. Cl. 326/38

(57) ABSTRACT

A device for performing a “logic function” including a magnetic structure including at least one first magnetoresistive stack including a first ferromagnetic layer and a second ferromagnetic layer separated by a non-ferromagnetic interlayer, the ferromagnetic hard layer being pinned in a fixed magnetic state which serves as a reference and at least one first and one second current line belonging to a first and a second level of metallization respectively, each of the two lines generating a magnetic field in the vicinity of the first stack when a current flows therethrough. The first and second lines are disposed at various distances of the second ferromagnetic layer, the various distances being determined by the “logic function”.

The present invention relates to a device for performing a logic function comprising a magnetic structure including at least one magnetoresistive stack including a first ferromagnetic layer and a second ferromagnetic layer separated by a non-ferromagnetic interlayer.

Spin electronics, also designated by the term “spintronics” is a rapidly expanding discipline, which consists of using the spin of an electron as an additional degree of freedom in comparison to classical, silicon electronics which uses only its charge. Indeed, spin has a significant influence on the transport properties in ferromagnetic materials. Numerous applications of spin electronics, particularly memories, or logic elements, use stacks of magnetoresistive layers comprising at least two ferromagnetic layers separated by one non-magnetic layer. The magnetization of one of the ferromagnetic layers is pinned in a fixed direction and serves as a reference layer while the magnetization of the other layer can be switched relatively easily by the use of a magnetic moment via a magnetic field or a spin-polarized current.

These stacks can be magnetic tunnel junctions (MTJ) when the separating layer is insulating or structures known as spin valves when the separating layer is metallic. In these structures, electrical resistance varies according to the relative orientation of the magnetization of the two ferromagnetic layers.

The magnetic tunnel junctions are nanostructures consisting of two ferromagnetic layers separated by an oxide layer. The magnetization of one of the ferromagnetic layers (called the “Hard Layer”, HL) is fixed. The stability of this layer can be provided by its shape or by exchange coupling with an Anti-FerroMagnetic (AFM) layer. The magnetization of the other layer (called the “Soft Layer”, SL) is variable. So the resistance of the stack depends on the relative orientation of the two ferromagnetic layers: this is the effect of the Tunnel Magneto Resistance [TMR]. The transition from a magnetization Parallel (P) to a magnetization Anti-Parallel (AP) will present a hysteretic behavior and the resistance value will then encode the information contained in the junction.

In ferromagnetic materials, there is a magneto-crystalline anisotropy due to the interactions between the magnetic moment and the crystalline network. The resulting direction is known as easy magnetization in which magnetization will naturally align in the absence of an outside influence. Shape anisotropy will add to this crystalline anisotropy, this time depending on the shape of the junction: for example, if an oval shaped junction is used, the shape anisotropy will tend to align the magnetization along the largest axis of the junction. If the magneto-crystalline easy magnetization axis is oriented along this same direction, the effects will add to and will receive a significant stability from the junction.

Giant magnetoresistor tunnel junctions are the storage elements of a new type of non-volatile magnetic memories. Associated with addressing arrays, they form MRAM (“Magnetic Random Access Memory”) memories. The intrinsic non-volatility of the magnetic devices, combined with a high integration density, a high write speed and a good immunity to radiation allow combining the qualities of all types of existing electronic memories and of exceeding the performances. In the scope of a memory use, the crucial features are integration density, speeds, and the reading and writing consumption.

Alongside the MRAM memories, a large field of application of these tunnel effect magnetoresistors is programmable logic. A programmable logic circuit is a circuit having functionality which can be programmed starting with a standard circuit. If this functionality can be modified several times, it is a reprogrammable circuit. The most currently used re-programmable circuits are FPGA (“Field Programmable Gate Array”), which are composed of basic programmable logic functions known as conversion tables (or LUT for “Look Up Table) interconnected to form a complex logic function. In these types of circuits, each LUT is operated by a code stored in memory. The logic gates or other logic elements can thus be designed using tunnel junctions or spin-valves. These elements benefit from the non-volatile character of the information which is processed, and from the possibility of re-programming the gate, i.e., to change the functionality (for example to transform an AND gate to NOR). Programmable logic problems are, therefore, close enough to those of memories, with some nuances, however:
Integration density is less critical than in the case of a memory (because the programmable logic memory elements only serve to store the circuit functionality and not a large quantity of data);
Speed and write consumption are also less critical, circuit functionality being programmed once and the circuit operation comprising only of a series of read cycles (except in the case of dynamic reconfiguration where the functionality of the circuit evolves over the course of its use).

The third large logic circuit family is that of non-reprogrammable logic circuits or ASIC's (Application Specific Integrated Circuits). In these circuits, the logic function is unchangeable and a circuit must be designed for each logic function. This approach is much more successful in terms of integration, but it necessitates the creation of a specific circuit, and as a result, is much more expensive than in a re-programmable approach. Here, there is no storage aspect: the logic function is generally broken down into elementary logic functions (“and”, “or” and “not”), called standard cells, and interconnected to form the desired logic function.

While the MRAMs and the FPGAs have been the subject of many studies, the work on non-reprogrammable magnetic logic is much less numerous. Indeed, the non-volatility and immunity to radiation of the MTJs predispose them more to a memory use. Further, these devices being passive, it is a priori not possible to directly connect two purely magnetic logic functions without deteriorating their function, unless to summon the CMOS components to regenerate the signal. Yet a logic function is generally broken down into elementary logic functions.

Moreover, in the case of a use of memory or FGPA, the logic signal is only transferred from one technology to the other (magnetic to CMOS and vice-versa) a small number of times; in other terms, the relationship between the number of magnetic components and the number of CMOS components is sufficiently large to render the approach viable. On the other hand, if a complex function is sought from the elementary logic functions, the logic signal must cross a significant number of basic logic cells, necessitating a double change of technology each time, the number of these changes becoming rapidly prohibitive. This can also be expressed by saying that the relationship noted above between the number of magnetic components and the number of CMOS components can quickly become unacceptable and the interest in using the magnetic components becomes questionable.

In this context, the purpose of this invention is to supply a device enabling the performance of non-reprogrammable logic functions starting with a magnetic structure free from the problems cited earlier.

To this end, the invention proposes a device performing a “logic function” comprising a magnetic structure composed of:
at least one first magnetoresistive stack including one first ferromagnetic layer and one second ferromagnetic layer separated by a non-ferromagnetic interlayer,
at least one first and one second current line belonging to a first and a second level of metallization respectively, each one of said two lines generating a magnetic field in the vicinity of said first stack when an electrical current flows through them,
   said device being characterized in that, for said at least one stack, said first and second lines are disposed to the various distances of said second ferromagnetic layer, said various distances being predetermined by said “logic function”.

What is meant by the distance between a line and the second layer is the distance separating the center of the second layer and the point of the line closest to said center of the second layer. The second layer will most often be a ferromagnetic soft layer while the first layer will most often be a ferromagnetic hard layer pinned in a fixed magnetic state serving as reference.

Additionally, what is meant by “logic function” is a function having a minimum threshold of Boolean complexity equivalent to at least one of the four functions “AND”, “OR”, “NOT AND”, or “NOT OR”. Consequently, the fact of reading or writing a memory is not considered as a logic function within the meaning of the invention.

It will be noted that the axes of symmetry of the current lines in the direction of the current and the center of the second layer are not necessarily in the same plane: in this case, it is a spatial “offset”.

In a manner analogous to semiconductor integrated circuits, the device in accordance with the invention is created by a plurality of interconnection layers comprising alternating conducting layers also called “levels of metallization” equipped with metalized conducting lines extending parallel to said layer and insulating layers crossed by conducting paths enabling an electrical connection between two levels of metallization. A level of metallization includes a plurality of conductive lines surrounded by regions created in dielectric material.

Moreover, in accordance with use, a magnetoresistive element which includes at least one ferromagnetic hard layer and one ferromagnetic soft layer separated by a non-ferromagnetic interlayer (metallic or insulating) is called a “magnetoresistive stack” or “magnetic tunnel junction”. In what follows, this element will be designated by the term “magnetoresistive stack”.

In such stacks, either of the ferromagnetic layers, or both, can themselves be formed by several ferromagnetic and non-ferromagnetic layers designed in such a way that the set is formed as a single ferromagnetic layer with improved performance, forming what is called a synthetic magnetic layer. In what follows, “magnetic layer” or “ferromagnetic layer” will be written interchangeably.

Playing with the distance between the write line and the soft layer will enable weighing the effect of a current in comparison with another current in another line and contribute to the logic function generation. In all known devices (memory cells for example), the distance of the line to the magnetoresistive stack is fixed and minimal for current density questions. On the contrary, in accordance with the invention the amplitude of the magnetic field will be varied by taking an interconnection topology with the various distances between the soft layer and the lines, the sum of the effects of each line being the expression of the sum of the generated magnetic fields.

The interconnection topology will thus consist of judiciously placing the write lines around the magnetoresistive stack in order to apply the total magnetic field necessary to orient the magnetization of the soft layer in relation to that of the hard layer in a way that the resulting tunnel resistance encodes the information wanted.

The invention thereby avoids the interconnection problems of elementary logic functions by using the topology of the write lines (ad hoc choice of the direction of the lines in relation to the magnetoresistive stacks, from the direction of the current carrying them and the distance between these lines and the stacks) thereby directly creating a sophisticated logic function, with the ability of being complex.

It will be noted that the current lines can have varied forms of wire or tape.

It will be noted that it is also possible to take the lines of various widths so that, with equal current and distance from the ferromagnetic layer, the magnetic field generated by a larger line is weaker that the magnetic field generated by a smaller line.

The device in accordance with the invention can also present one or several of the features below, considered individually or according to all the technically possible combinations:
said first and second lines are situated on either side of said magnetoresistive stack;
said first line is situated at a distance d1 above said soft layer and said second line is situated at a distance d2 below said soft layer, so that, for two currents of the same intensity flowing respectively in said first line and said second line, the intensities H1 and H2 of the fields generated respectively by said first and second lines in the vicinity of said soft layer are such that:

$$\frac{{H}_{1}}{{H}_{2 }} = \frac{{d}_{2}}{{d}_{1}} ;$$

in accordance with the invention, the device is comprised of:
   at least one first magnetoresistive stack including one first ferromagnetic layer and one second ferromagnetic layer separated by a non-ferromagnetic interlayer,
   at least one first and one second current line belonging to a first and a second level of metallization respectively, each one of said two lines generating a magnetic field in the vicinity of said at least one stack when they are crossed by an electrical current,
said first and second lines being disposed to equal distance on both sides of said second ferromagnetic layer.
said magnetic structure is comprised of:
   a second magnetoresistive stack which can be either merged with said first stack or different from said first stack, said second stack, said second magnetoresistive stack including a first ferromagnetic layer and a second ferromagnetic layer separated by a non-ferromagnetic interlayer.
   a current line situated in the vicinity of said second magnetoresistive stack and generating a magnetic field in the vicinity of said second stack when an electrical current flows through it, said third line comprising at least two current input points so that two currents add in said line;
said line situated in the vicinity of said second magnetoresistive stack is connected to at least one other current line belonging to a level of metallization different from the level of metallization of said line situated in the vicinity of said second magnetoresistive stack, the two lines being connected by an interconnection conductive line and the point of connection between said interconnection line and said line situated in the vicinity of said second magnetoresistive stack forming one of said two current input points;
said at least two current input points inject a current I1 and I2 respectively in said line situated in the vicinity of said second magnetoresistive stack so that the intensity H′ of the field generated by said third line in the vicinity of said soft layer is such that

$$\frac{{H}^{′}}{H} = \frac{{I}_{1} + {I}_{2}}{I}$$

where H is the intensity of the magnetic field by said current line situated in the vicinity of said second magnetoresistive stack when a current I flows through it;
the first ferromagnetic layer(s) are hard ferromagnetic layers pinned in a fixed magnetic state which serves as a reference and the second ferromagnetic layer(s) are soft ferromagnetic layers;
the soft layer(s) present(s) a circular or semi-circular shape minimizing the write current necessary for the variation of their magnetic orientation;
the hard layer of each one of the magnetoresistive stacks is pinned in a magnetic state perpendicular to an easy magnetization axis serving as reference for the soft layer of the same stack, this magnetoresistive soft stack presenting a variable magnetic orientation by the current coming from the current line(s) situated in the vicinity of the magnetoresistive stack in a way leading to a modification of the transversal resistance of the stack sufficient to trigger an electric signal, this variation of the magnetic orientation of the soft layer of the stack being sufficiently weak so that the orientation does not switch between two stable positions but fluctuates around a stable position;
the device in accordance with the invention is comprised of a current input interface comprising:
   at least one input receiving logic information encoded in the form of a voltage level representing a logical ‘0’ or ‘1’;
   at least one output connected to an interconnection conductive line;
   the electronic means for generating a current in said interconnection conductive line having a direction that is representative of the logic information, the absolute value of the intensity of said current being identical in either direction of said current;
the device in accordance with the invention is comprised of an output inter-race electrically connected to said at least one first magnetoresistive stack, said interface comprising:
   a current input connected to an interconnection conductive line electrically connecting said current input to said at least magnetoresistive stack;
   the means for measuring the current flowing in said at least one first stack, the current representative of the magnetic state of said at least first stack;
   the means for generating a voltage representative of said magnetic state according to said current.
the device in accordance with the invention is comprised of:
   a second magnetoresistive stack including a ferromagnetic hard layer and a ferromagnetic soft layer separated by an non-ferromagnetic interlayer layer, the ferromagnetic hard layer being pinned in a fixed magnetic state which serves as reference;
   an output interface electrically connected to said first and second magnetoresistive stacks, said interface comprising:
      a first current input connected to an interconnection conductive line electrically connecting said first current input to said first magnetoresistive stack;
      a second current input connected to an interconnection conductive line electrically connecting said second input to said second magnetoresistive stack;
      the means for generating a differential current between the current flowing in said first stack and the current flowing in said second stack when they are subjected to a bias voltage, said differential current being representative of a logic information;
      the means for generating a voltage representative of said logic information according to said differential current.
said input and/or output interface is performed in CMOS technology;
said magnetic structure is situated above said interface(s) by CMOS technology;
the non-ferromagnetic interlayer junction is made of magnesium oxide MgO.
The device in accordance with the invention is comprised of at least two lines of different widths situated in the vicinity of, a magnetoresistive stack.

This invention also serves the purpose of an adder comprising:
a current input interface of current signals I_{A}, I_{B} and I_{Cin} magnetizing three interconnection lines,
a magnetic structure comprising:
   a said magnetic part of said sum generation,
   a said magnetic part of said carry generation,
      said magnetic part of said sum generation:
a first magnetoresistive stack including a ferromagnetic hard layer and a ferromagnetic soft layer separated by an non-ferromagnetic interlayer, the ferromagnetic hard layer being pinned in a fixed magnetic state which serves as reference;
a second magnetoresistive stack including a ferromagnetic hard layer and a ferromagnetic soft layer separated by an non-ferromagnetic interlayer, the ferromagnetic hard layer being pinned in a fixed magnetic state which serves as reference;
a first, second and third current line belonging to a first, second and a third level of metallization respectively,
a first, second and a third vertical conductive via with access to said input interface electrically connected to said first, second and third current line respectively, so that the first vertical via injects the current I_{B} in said first line, said second vertical via injects the current I_{A} in said second line and said third vertical via injects the current I_{Cin} in said third line,
   said second current line generating a magnetic field in the vicinity of said first and second stack and being situated at a distance d along the vertical axis of the soft layers of each of said first and second stack,
   said first current line generating a magnetic field in the vicinity of said first stack and being situated at a distance 2×d along the vertical axis of the soft layer of said first stack,
   said third current line generating a magnetic field in the vicinity of said first and second stack and being situated at a distance 2×d along the vertical axis of the soft layers of each one of said first and second stack,
   said first current line being electrically connected to said third current line through a vertical interconnection via so that the currents I_{B} and I_{Cin} of said first and third lines are added before being routed over the branch of said third current line generating a magnetic field in the vicinity of said second stack,
   said second current line being substantially perpendicular to said first and third current lines in the vicinity of said first stack and said second current line being substantially perpendicular to said third current line in the vicinity of said second stack.

The adder in accordance with the invention can also present one or several of the features below, considered individually or according to all of the technically possible combinations:
said magnetic part of said carry generation comprising:
   a third magnetoresistive stack including a ferromagnetic hard layer and a ferromagnetic soft layer separated by an non-ferromagnetic interlayer, the ferromagnetic hard layer being pinned in a fixed magnetic state which serves as reference;
   a fourth magnetoresistive stack including a ferromagnetic hard layer and a ferromagnetic soft layer separated by an non-ferromagnetic interlayer, the ferromagnetic hard layer being pinned in a fixed magnetic state which serves as reference;
   a fourth current line belonging to said first level of metallization, said fourth current line generating a magnetic field in the vicinity of said third and fourth stack and being situated at a distance d along the vertical axis of the soft layers of each one of said third and fourth stacks,
   a fourth and fifth vertical conductive via electrically connecting said fourth current line to said second current line respectively in which current I_{A} flows, and to said branch of said third current line in which the sum of currents I_{B}+I_{Cin} flows, so that the currents I_{B}+I_{Cin} and I_{A} are added before being routed over said fourth current line generating a magnetic field in the vicinity of said third and fourth stacks.
said magnetic structure includes:
   a fourth current line, known as a carry-propagation line, belonging to said first level of metallization,
   a fourth and fifth vertical conductive via electrically connecting said fourth current line to said second current line respectively in which current I_{A} flows, and to said branch of said third current line in which the sum of currents I_{B}+I_{Cin} flows, so that the currents I_{B}+I_{Cin} and I_{A} are added before being routed over said fourth current line,
   a fifth current line belonging to a level of metallization different from said first level of metallization and suitable for producing a magnetic field in the vicinity of a magnetoresistive stack,
   a sixth vertical conductive via electrically connecting said fourth current line to said fifth current line.
the adder in accordance with the invention is comprised of:
   a seventh vertical conductive via electrically connected to said carry-propagation line;
   a current limiting circuit for regulating the absolute value of the current flowing in said carry-propagation line; said current limiting circuit being connected to said propagation line by said seventh conductive via.
said limiting circuit is comprised of three PMOS transistors and three NMOS transistors mounted in series, the first PMOS transistor and the third NMOS transistor having a common gate, the second PMOS transistor and the second NMOS transistor having a common gate, the third PMOS transistor and the first NMOS transistor having a common gate, the common drain of the first NMOS transistor and the third PMOS transistor being connected to said carry-propagation line by said seventh vertical conductive via.

The purpose of this invention is also an “AND” logic gate comprising:
an input interface of current signals I_{A} and I_{B},
a magnetic structure comprising:
   a magnetoresistive stack including a ferromagnetic hard layer and a ferromagnetic soft layer separated by an non-ferromagnetic interlayer, the ferromagnetic hard layer being pinned in a fixed magnetic state which serves as reference;
   a first, second and third current line belonging to a first, second and a third level of metallization respectively,
      said second current line receiving a predetermined constant current by generating a magnetic field in the vicinity of said stack and being situated a distance d along the vertical axis of the soft layer of said stack,
      said first current line receiving current I_{A} generating a magnetic field in the vicinity of said stack and being situated at a distance 2×d along the vertical axis above the soft layer of said stack,
      said third current line receiving current I_{B} generating a magnetic field in the vicinity of said stack and being situated at a distance 2×d along the vertical axis below the soft layer of said stack.

Other features and advantages of the invention will result clearly from the description which is given below, as indicative and not in the least limiting, in reference to the attached figures, among which:

FIG. 1 is a simplified schematic representation of the magnetic field generated by an infinitely long current line;

FIGS. 2a) and 2b) represent a magnetoresistive stack and an infinitely long rectilinear conductive wire;

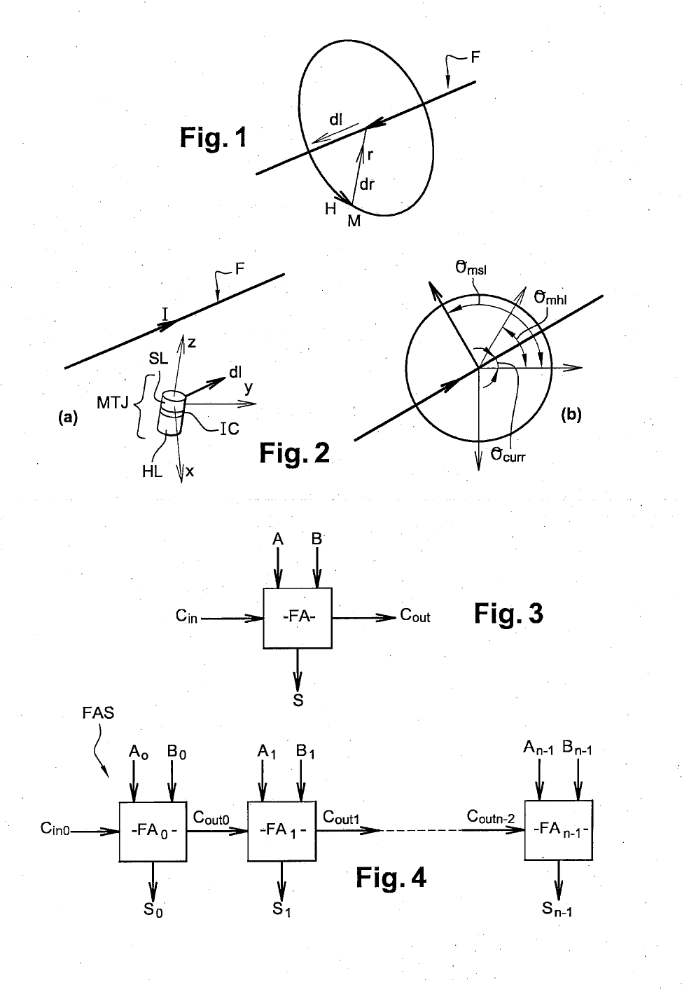

FIG. 3 represents a binary, full 1-bit adder;

FIG. 4 represents a binary full n-bit adder;

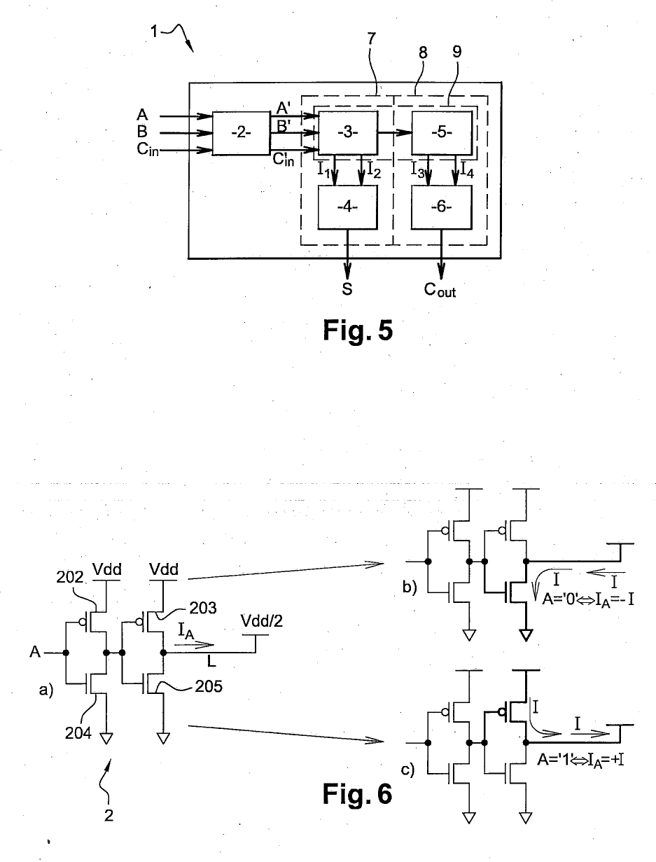

FIG. 5 illustrates the architecture of a device for performing an adder logic operation in accordance with the invention;

FIGS. 6a) to 6b) illustrate the performance mode of a current input interface of the device in FIG. 5;

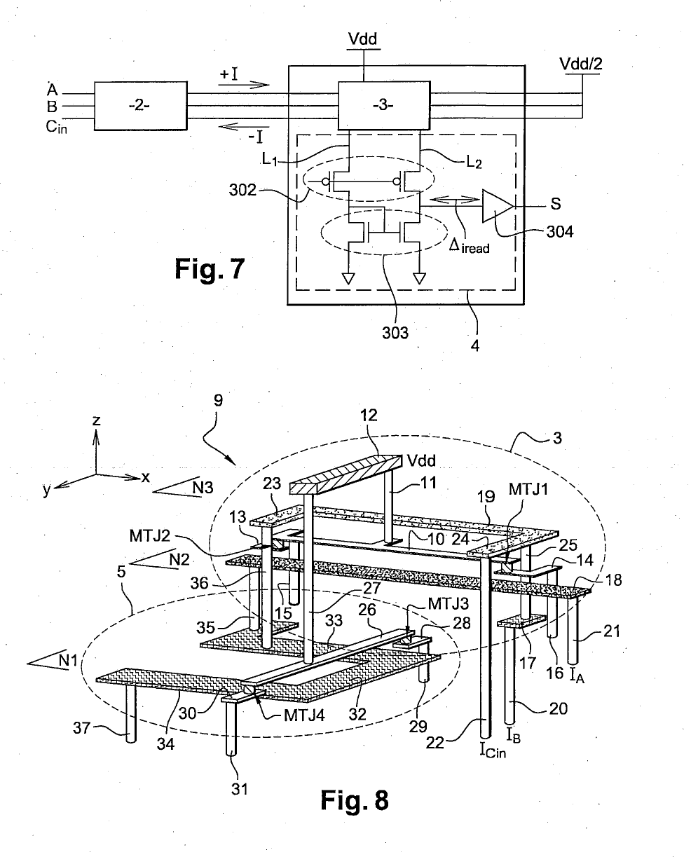

FIG. 7 illustrates a performance mode of an output interface of the device in FIG. 5;

FIG. 8 represents a three dimensional view of an operation mode of the sum and carry generation magnetic parts of the device in FIG. 5;

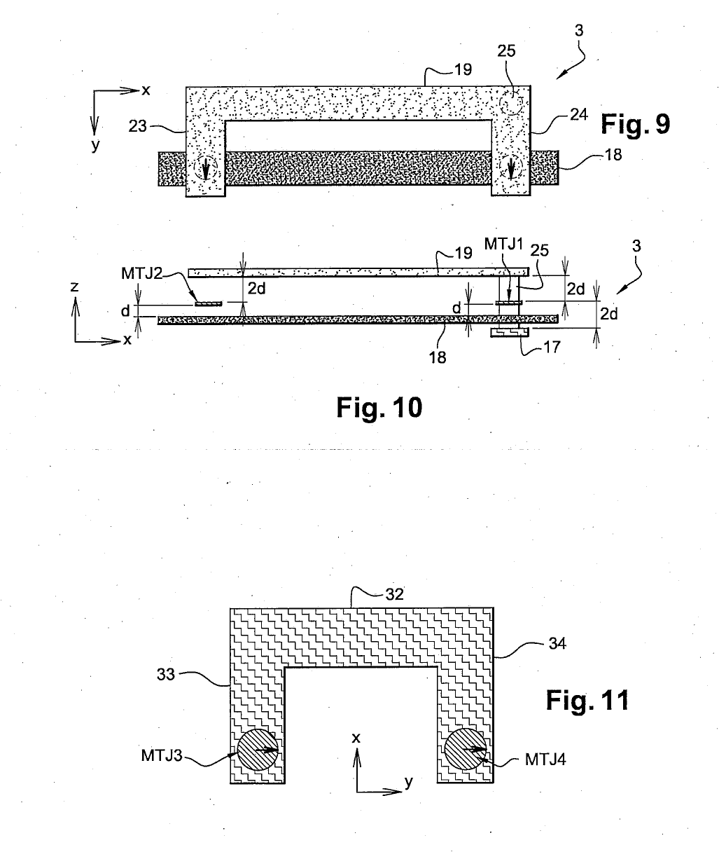

FIGS. 9 and 10 represent a view from above and a view across respectively, of the sum generation magnetic part such as shown in FIG. 8;

FIG. 11 represents a view from above of the carry generation magnetic part such as shown in FIG. 8;

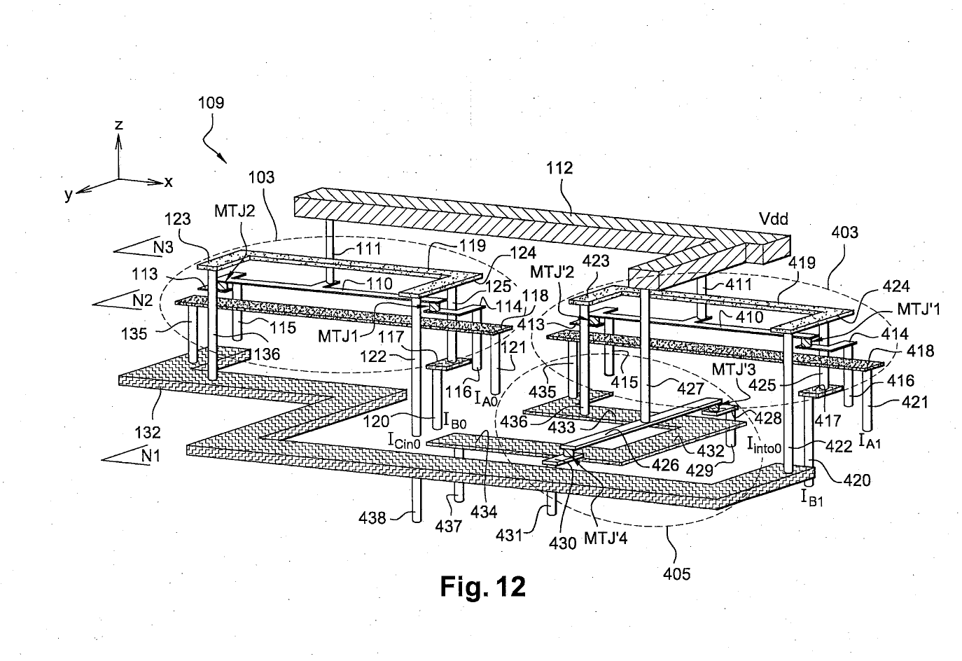

FIG. 12 represents a three dimensional view of a 2-bit adder in accordance with the invention with carry propagation;

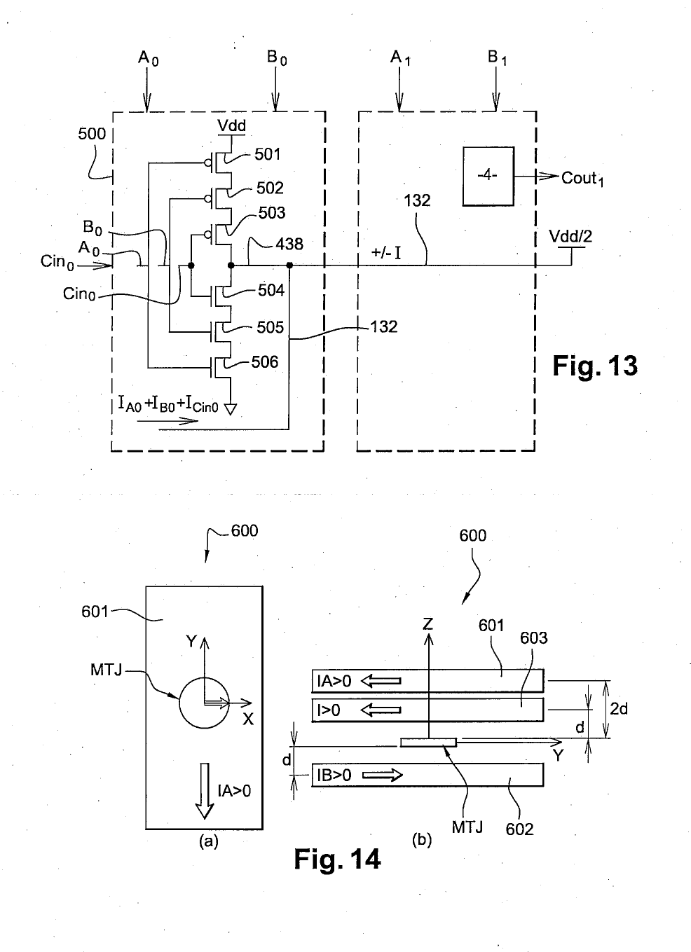

FIG. 13 represents a current limiting circuit used for the 2-bit adder in FIG. 12;

FIGS. 14 a) and b) schematically represent a device for the operation of an “and” gate logic in accordance with the invention seen from above and a lateral cross-section, respectively.

In every figure, the common elements bear the same reference numbers.

In order to illustrate the notion of interconnection topology, we will first qualify the magnetic field generated in a point of space by a current distribution. Let a local current density \vec{j} in a point M′ of space be marked by its vector position \vec{r}′. The magnetic field generated by \vec{j}(\vec{r}′) in a point M marked by its vector position \vec{r}′ is given by the Biot and Savart law:

$$d \vec{H} ( r ) = \frac{\vec{j} ( {r}^{\vec{′}} ) \times ( \vec{r} - {\vec{r}}^{′} )}{4 π {\vert \vec{r} - {\vec{r}}^{′} \vert}^{3}} . \qquad ( 1 )$$

Note that the sign × designates the vectorial product.

The total magnetic field obtained for a distribution of current densities V is obtained by integrating this equation over the volume V:

$$\vec{H} ( \vec{r} ) = \int \int {\int }_{V} \frac{\vec{j} ( {r}^{\vec{′}} ) \times ( \vec{r} - {\vec{r}}^{′} )}{4 π {\vert \vec{r} - \vec{r} \vert}^{3 }} d V . \qquad ( 2 )$$

For the purpose of simplification, in what follows we will assimilate the write line to an infinitely long wire and we will consider the case of a magnetic field generated by a current I flowing through this infinitely long wire. The cross-section of this wire has radius R. As illustrated in FIG. 1, the wire F passes at a distance r from a point M such that r>>R, where d\vec{l} is a unitary vector having the direction and orientation of the current and d\vec{r} is a unitary vector perpendicular to the current line and passing through M. In this specific case, the value of the field \vec{H} in M is given by the following equation:

$$\vec{H} = \frac{I}{2 π r} d \vec{r} \times d \vec{l} . \qquad ( 3 )$$

It can be noted again that in this approximation, the value of the field depends on the direction, the orientation and the value of the current, as well as the distance from the line to the considered point.

Consider now for example that the point M represents the center of the ferromagnetic soft layer SL of a magnetoresistive stack MTJ such as shown in FIGS. 2 a) comprising in addition a ferromagnetic hard layer HL and a non-ferromagnetic interlayer IC separating the layers SL and HL. A current I is always flowing through a current line F. With the conventions of FIG. 2 b) where θ_{curr}, ζₘₛₗ and θₘₕₗ are the angles formed respectively by the current line F, the magnetization of the soft layer SL, and the magnetization of the hard layer HL, with the easy magnetization axis of the soft layer (situated along the y axis of an xyz coordinate system in which the x axis is perpendicular to y in the plane of the sheet and z is perpendicular to the plane of the sheet). The magnetic field applied to the center of the soft layer is given by the following equation:

$$\vec{H} = \frac{I}{2 π r} d \vec{r} \times d \vec{l} = \frac{I}{2 π r} ( \begin{matrix}- cos {θ}_{curr} \\ - sin {θ}_{curr} \\ 0\end{matrix} ) . \qquad ( 4 )$$

If we consider that we do not have shape anisotropy and that the magneto-crystalline anisotropy field is insignificant in comparison to the field applied, we can consider in a first approximation that the magnetic moment will be aligned over the generated field.

If we consider the example where the magnetization of the hard layer is perpendicular to the easy magnetization axis (i.e. θₘₕₗ=90°), we can then easily choose the direction of the currents to apply for obtaining the parallel (noted by P), anti-parallel (noted by AP) or intermediate (noted by INT) states of the magnetoresistive stack as illustrated in table 1 below (we designate the resistance of the magnetoresistive stack MTJ in its parallel state by R_{P}, R_{AP} is the resistance of the magnetoresistive stack in its anti-parallel sate and R_{INT} is the resistance of the magnetoresistive stack in an intermediate state such as R_{AP}>R_{INT}>R_{P}).

TABLE 1

| | | | Resistance of the |
|---|---|---|---|
| | | | magnetoresistive |
| θ_{curr} | θₘₛₗ | State | stack |
| 0 | 90° | Parallel | R_{P} |
| 180° | 270° | Anti-parallel | R_{AP} |
| 90° | 180° | Intermediate | R_{INT} |

Suppose now that we have two current lines L₁ and L₂, located respectively at distances r₁ and r₂ from the center of the soft layer, we will generate a field, the value of which is given by the following equation:

$$\vec{H} = \frac{I}{2 π r} d \vec{r} \times d \vec{l} = \frac{{I}_{1}}{2 π {r}_{1}} ( \begin{matrix}- cos {θ}_{curr}^{1} \\ - sin {θ}_{curr}^{1} \\ 0\end{matrix} ) + \frac{{I}_{2}}{2 π {r}_{2}} ( \begin{matrix}- cos {θ}_{curr}^{2} \\ - sin {θ}_{curr}^{2} \\ 0\end{matrix} ) , \qquad ( 5 )$$

where θ_{curr}¹ and θ_{curr}² are the angles formed respectively by the two current lines L₁ and L₂ with the easy magnetization axis of the hard layer.

By applying the preceding result to two lines, the first line being situated at a distance d₁ above the soft layer and the second line being situated at a distance d₂ below the soft layer, for two currents of the same intensity flowing in the first line and in the second line respectively, the intensities H1 and H2 of the fields generated by the first and second lines respectively in the vicinity of the soft layer are then such that:

$$\frac{{H}_{1}}{{H}_{2}} = \frac{{d}_{2}}{{d}_{1}} .$$

Thus, the choice of the direction of the two current lines and the direction and the intensity of the two currents flowing through them enables choosing the exact direction and intensity of the generated magnetic field and therefore, the direction of the magnetization in the field. This approach may be generalized to n conductive wires. Of course, this example is only given as an illustration: generally, any choice of the position of the lines in three dimensions (expressed by a choice of the topology of the interconnection layers), the direction and the value of each current can be used to perform a more or less complex logic operation as we will show in the details of what follows starting from two embodiment examples of a magnetic full adder: by magnetic full adder we mean an adder which contains a carry input and output of a kind that can be interlaced with another magnetic full adder.

It can be noted, furthermore that the intensity of the generated magnetic field depends directly on the intensity of the current flowing through the line. Consequently, by adding the input currents arriving on the same line through an ad hoc interconnection of several conductive lines arriving on said line (Kirchhoff's laws), we can modify the value of the intensity of the magnetic field, the intensity of the generated field thus being, for example, two times higher for line with current 2×l flowing through it than for a line situated at the same distance from the soft layer and having a current flow l.

In a known way, the processors contain four operational systems:
the memory circuits (code, data),
the control circuits (bus arbiters, energy management blocks, etc.),
the input-output circuits enabling the dialogs between processing circuitry (“on-chip”) or with external circuitry (“off-chip”),
the core processor called “core” or “datapath” dedicated to information processing (i.e., performing the calculation).

The “standard” core of a processor is generally made up of a set of interconnected operational blocks, performing the purely logical basic combination operations (“AND”, “OR”, etc.) or arithmetic (addition, multiplication, comparison, difference), the set being driven by control blocks. According to the use targeted, we will favor the speed of the core (calculation time for performing a given operation, the speed being often dependent on the type of operation according to more or less critical paths in the core and on the type of data to process) or the maximum energy to dissipate for a given operation. A majority of the current cores work on 32-bit or 64-bit words. A same operation needs to be performed on each one of the bits of the word, the core is then made up (for a 32-bit word for example) of 32 identical slices working in parallel: each slice operated on 1 bit of data (“bit sliced” architecture). The operation of a 32-bit core thus comes down to the performance and to the optimization of a single slice which will be repeated as many times as the number of bits making up the word. This approach is particularly valid for an adder which is one of the constituents of the core. Addition is also the most used arithmetic operation but is also the limiting block of the core in terms of processing speed. The architecture of the adder is thus critical, there is currently a number of approaches (in CMOS technology) aimed at optimizing it, we find circuit level or logic level optimizations (like the “carry lookahead adder”). A binary full adder FA is illustrated in FIG. 3. A and B are bits to be added. Cᵢₙ (“carry in”) represents the carry coming from a preceding sum (in the case of a summation on n bits) and Cₒᵤₜ (Cᵢₙ of the next adder) represents the resulting carry of the calculation (“carry out”). The truth table of such an adder FA is given in table 2 below.

TABLE 2

| A | B | Cᵢₙ | S | Cₒᵤₜ |
|---|---|---|---|---|
| 0 | 0 | 0 | 0 | 0 |
| 0 | 0 | 1 | 1 | 0 |
| 0 | 1 | 0 | 1 | 0 |
| 0 | 1 | 1 | 0 | 1 |
| 1 | 0 | 0 | 1 | 0 |
| 1 | 0 | 1 | 0 | 1 |
| 1 | 1 | 0 | 0 | 1 |
| 1 | 1 | 1 | 1 | 1 |

There are several kinds of CMOS architecture enabling the performance of a binary full adder (Static Adder, Mirror Adder, Transmission-Gate-Based Adder), the objectives being essentially to minimize the cost of silicon and the calculation time of the full n-bit adder. We can create an n-bit adder by cascading n adders FA₀ to FAₙ₋₁, each adder being an adder such as shown in FIG. 3. An example of such a full n-bit FAS adder in series is shown in FIG. 4. In this configuration, the carry output Couti, of the FA; adder is injected in the carry input of the adder FAᵢ₊₁. This structure shows that the calculation time tₚ^{adder} (or the full adder propagation time) essentially depends on the calculation time of the carry as well as its propagation across the chain (thus depending on the n number of bits). When it increases, it is necessary to move to a system logic optimization approach to decrease the propagation time, passing from a linear complexity as here (tₚ^{adder} ∝n) to a root n complexity or logarithmically (tₚ^{apper} ∝\sqrt{n}) or (tₚ^{adder} ∝ ln n), for example by implementing carry lookahead adders.

According to a particularly advantageous performance mode of this invention, it is possible to move from a purely CMOS technology such as presented above to a technology combining magnetic technology with CMOS technology for creating a full hybrid circuit adder, the entire calculation being performed by the magnetic part. FIG. 5 illustrates the architecture of a device for the performance of a logic adder 1 operation in accordance with the invention.

Adder 1 has three logic inputs A, B Cᵢₙ, A and B making up the bits to add and Cᵢₙ making up the carry of the preceding adder, and two logic outputs S and Cₒᵤₜ making up the sum and carry respectively such as defined by reference to the truth table of table 2. Logic inputs A, B and Cᵢₙ correspond to the voltage levels corresponding to the ground if the logic value is 0, and to a bias voltage of a MOS transistor gate if the logic value is 1.

The adder has:
a first block 2 input interface performed in CMOS technology of current signal generation I_{A}, I_{B} and I_{Cin} flowing through three interconnection lines having an orientation which depends on the logic information applied on input;
a second block 7 of sum generation S;
a third block 8 of carry generation Cₒᵤₜ.

The second block 7 of sum generation S has:
a magnetic part 3 operating in differential mode and generating two magnetoresistive information outputs I1 and I2;
an output interface 4 performed in CMOS technology enabling conversion of magnetoresistive information I1 and I2 in a CMOS S compatible voltage.
In a similar fashion, the third block 8 of carry generation Cₒᵤₜ has:
a magnetic part 5 operating in differential mode and generating two magnetoresistive information outputs I3 and I4;
an output interface 6 performed in CMOS technology enabling conversion of magnetoresistive information I3 and I5 in a CMOS Cₒᵤₜ compatible voltage.

The hybrid adder 1 presents as a system where the magnetic parts 3 and 5 (as well as the topology of the interconnection system as we will see next) perform the arithmetic operation and the CMOS part (the input interface 2 and the output interfaces 4 and 6) acts as the interface with the outside world.

A performance mode of input interface 2 is shown in FIG. 6 a). This interface 2 illustrates the generation of the current I_{A} from the logic information A; two other analog circuits can be used for the generation of I_{B} from B and I_{Cin} from Cᵢₙ.

According to the invention, the input interface 2 is entirely performed in CMOS technology. This interface 2 has four transistors 202-205 mounted two by two in CMOS inverters connected in series. In the case in point, the transistors of the pair 202-203 are PMOS while the transistors of the pair 204-205 are NMOS (for Positive Metal Oxide Semiconductor and Negative Metal Oxide Semiconductor, respectively).

The PMOS transistors 202 and 203 (symbolized by a circle attached to their gates) have their common sources connected to a positive voltage supply and the NMOS transistors 204 and 205 have their common sources connected to the ground.

The PMOS 202 and NMOS 204 transistors have their common drains and the PMOS 203 and NMOS 205 transistors have their common gates, the common drain of transistors 202 and 204 being connected to the common gate of transistors 203 and 205.

The PMOS 203 and NMOS 205 transistors have their common drains connected to a supply source equal to half the positive voltage supply.

The PMOS 202 and NMOS 204 transistors have their common gates and receive logic information A on this gate. In accordance with the CMOS logic, this logic information A is encoded in the form of a zero voltage level if the binary information is 0 (so that the NMOS transistor 204 is “off” and the PMOS transistor 202 is turned on) and in the form of a positive voltage level if the binary information is 1 (so that the NMOS transistor 204 is turned on and the PMOS transistor 202 is “off”),

Thus, if the logic information to transmit is “‘A’=0”, the NMOS 204 and PMOS 203 transistors are “off” while the PMOS 202 and NMOS 205 transistors are turned on and reciprocally if “‘A’=1”, the NMOS 204 and PMOS 203 transistors are turned on while the PMOS 202 and NMOS 205 transistors are “off”.

L designates the interconnection line through which current I_{A} flows representative of the logic information A. By considering the current I as positive entering into line L forming the interconnection system (connected to the drains and polarized to Vdd/2) and the exiting current as negative, we can thus write the following equivalence by referencing the FIGS. 6 b and 6 c):

A=‘0’ [symbol] I_{A}=−I (FIG. 6c))

A=‘1’ [symbol] I_{A}=I. (FIG. 6b)).

Thus, the current I_{A} will be negative in the case where the A information is ‘0’ and positive in the case where the A information is ‘1’.

I designates the absolute value of the current generating a local field H in the center of the soft layer used in a device in accordance with the invention and sufficiently intense to enable passing from the parallel state to the anti-parallel state. This “current mode” approach also considers the possibility of working with relatively low voltage supplies (which is significant in the current “downscaling” perspective).

As the write current flows in the interconnection line L according to opposite directions (round-trip), it is sometimes qualified as bidirectional current.

Thus, contrary to CMOS logic, where the information is encoded in the form of a voltage level, the logic of the magnetic part uses currents of equivalent levels for the two binary values but in opposite directions.

The input block 2 enables the conversion of the logic information in voltage mode (compatible CMOS levels) into a current having sufficient level to vary the magnetic state of the magnetoresistive stacks across the generated fields in the interconnection circuits.

The output interfaces 4 and 6 are performed in CMOS technology. FIG. 7 illustrates the performance mode of output 4, the output interface 6 able to be performed in an identical manner.

FIG. 7 thus illustrates the output interface 4 electrically connected through two interconnection conductive lines L1 a L2 to the magnetic part 3 (to which we will revisit next) receiving the logic information encoded in the form of current +I or −I from input interface 2. The magnetic part 3 includes two magnetoresistive stacks polarized with the help of the positive voltage supply and generating a current I1 and I2 respectively in the conductive lines L1 and L2, these currents depend on the electric resistance of each stack (this resistance itself depends on the orientation of the magnetic field of the soft layer in relation to the orientation of the magnetic field of the hard layer serving as reference).

The output interface 7 is comprised of:

a “clamp” circuit 302;

a mirror circuit current differentiator 303;

a buffer amplifier element 304;

The “clamp” circuit 302 (acting as a voltage regulator) is composed of two PMOS transistors having gates which are connected, each PMOS transistor receiving its supply respectively from current I1 and current I2. These two PMOS clamp transistors regulate the bias voltage V_{bias} of the magnetoresistive stacks through the means of a setting operated by acting on the voltage V_{clamp} which is applied to the two gates.

As FIG. 7 shows, the currents coming from the drains of each one of these PMOS transistors are then compared with the means of the current differentiator mirror 303. To form such a current differentiator mirror 303, we use two NMOS transistors having gates which are brought to the potential of the drain of one of them generating the differential current Δi_{read} which attacks the “buffer” amplifier 304 or output buffer. This differential current Δi_{read} is representative of the difference of resistance ΔR between the two magnetoresistive stacks.

According to the direction of the current Δi_{read}, the current differentiator mirror 303 loads or unloads the buffer amplifier element 304. This buffer element has the role of regenerating the digital information by converting it to the form of a voltage S compatible with the logic levels of the CMOS components.

The output interface thereby converting the magnetoresistive information I1 and I2 into a compatible CMOS voltage. Thus we have the example:

for a ΔR>0, ‘S=1’ (i.e. S has the voltage level corresponding to a logical 1);

for a ΔR<0, ‘S=0’ (i.e. S has the voltage level corresponding to a logical 0);

FIG. 8 represents a three dimensional view according to an xyz orthogonal reference frame (x designating the axis of the abscissa and y designating the axis of the coordinates so that xy is forming the horizontal plane and z designating the vertical axis) of a performance mode of the magnetic circuit 9 of the adder device such as shown in FIG. 5 including the sum generation magnetic part 3 and the carry generation magnetic part 5.

The sum generation magnetic part 3 is comprised of:
a first magnetoresistive stack MTJ1 including a ferromagnetic hard layer and a ferromagnetic soft layer separated by a non-ferromagnetic interlayer.
a second magnetoresistive stack MTJ2 including a ferromagnetic hard layer and a ferromagnetic soft layer separated by a non-ferromagnetic interlayer.

It is noted that the various layers of the two stacks MTJ1 and MTJ2 are not shown, for clarity. The ferromagnetic soft layer is created in a magnetically soft material such as Permalloy, for example. Its magnetization responds easily to the variations of an outside magnetic field which is applied. This layer is preferably fine enough so that its magnetization can turn in a significant fashion under the effect of weak magnetic flows. The ferromagnetic hard layer presents a pinned magnetization. Moreover, the layer of the non-ferromagnetic interlayer can be made of magnesium oxide MgO: such a material thereby obtaining an elevated magnetoresistance TMR (Tunnel Magnetic Resistance) and a nominal weak resistance. As a reminder, in a known way, the electrical resistance of a stack of magnetic layers is given in first approximation (weak bias voltage and ambient temperature) by the relationship:

R_{MTJ}=Rₚ.(1+TMR.(1−cos θ)/2)

where:
Rₚ. is the nominal resistance of the magnetoresistive stack when the magnetizations of the two layers of the stack are oriented in the same direction;
TMR represents the magnetoresistance tunnel, i.e., the relative variation of resistance between the extreme orientation states;
θ is the angle formed between the orientations of the hard and soft layers.

Thus, when θ equals 0, the magnetoresistive stack is in a parallel state where the stack resistance in its parallel state R^{p} reaches its minimum and equals R_{MTJ}^{p}=Rₚ, whereas when θ=π, the magnetoresistive, stack is in an anti-parallel state and the electrical resistance of the stack in its anti-parallel state R_{MTJ}^{ap} is maximum and equals R_{MTJ}^{ap}=Rₚ.(1+TMR).

Preferably, the soft layers present a circular or semi-circular shape minimizing the write current necessary for the variation of their magnetic orientation. More generally, the stacks used have the form of circular or semi-circular and non-elliptical section contacts: unlike the memories, indeed, here we are attempting to obtain magnetoresistive stacks created so that the stability of the easy magnetization axes are weak, a manner in which the weak magnetic field suffices to set aside this position, the aim here not being the stable preservation of the information as in the case of a memory.

The MTJ1 and MTJ2 stacks are connected at their upper part by an upper common electrode 10 of polarization substantially directed along the x axis. This upper electrode is connected to a rail 12 of positive voltage supply directed along the y axis by a vertical conductive via 11.

The MTJ1 stack is connected at its lower part by a lower electrode 14 connected to a vertical conductive via 16. This conductive via 16 supplies the current I1 forming the input of the output interface 3 illustrated in FIGS. 5 and 7.

The MTJ1 stack is connected at its lower part by a lower electrode 13 connected to a vertical conductive via 15. This conductive via 15 supplies the current I1 forming the input of the output interface 3 illustrated in FIGS. 5 and 7.

As we have already mentioned above, the magnetic circuit 9 is created by a plurality of interconnection layers comprising alternating conducting layers also called “levels of metallization” equipped with metalized conducting lines extending parallel to said layer and insulating layers crossed by conducting vias enabling an electrical connection between two levels of metallization. A level of metallization includes a plurality of conductive lines surrounded by regions created in dielectric material.

The magnetic circuit 9 is formed by three levels of metallization N1 to N3 which will enable the injection of the input currents I_{A}, I_{B} and I_{Cin} transmitted by the input interface 2 as illustrated in FIG. 6. We note that the upper electrode 10 and the lower electrodes 13 and 14 of the magnetoresistive stacks MTJ1 and MTJ2 form two other levels of metallization respectively not referenced in FIG. 8.

In what follows we will describe three levels of metallization N1 to N3 in more detail.

Each level of metallization is formed by one or several current lines aimed at orienting the magnetic field of the various opposing soft layers:
The level of metallization N1 is represented by chevrons;
The level of metallization N2 situated above the level of metallization N1 is represented by heavy dotted lines;
The level of metallization N3 situated above the level of metallization N2 is represented by dotted lines which are more scattered than for level N2.

The sum generation magnetic part 3 includes three conductive lines 17, 18, 19 belonging to the levels of metallization N1, N2 and N3 respectively. FIGS. 9 and 10 represent respectively views from above the sum generation magnetic part 3 in the xy plane (seen from above) and xz (face view).

The MTJ1 and MTJ2 stacks are represented by dotted arrows in FIG. 9 with a solid arrow symbolizing the magnetic orientation of the hard layer serving as reference. The magnetization of the hard layers of the two stacks MTJ1 and MTJ3 are positioned in the same direction (note furthermore that we will use the same orientation of the hard layer for the two other hard layers of the stacks MTJ3 and MTJ4 described later in the text).

Three vertical conductive vias 20, 21 and 22 with access to the CMOS input interface such as shown in FIGS. 5 and 6 are electrically connected to the lines 17, 18 and 19 respectively. The vertical via 20 thereby injects the current I_{B} equal to +1/−1 (corresponding to the voltage level B) in line 17. The vertical via 21 thereby injects the current I_{A} equal to +1/−1 (corresponding to the voltage level A) in line 18. The vertical via 22 thereby injects the current I_{Cin} equal to +/−I (corresponding to the voltage level Cᵢₙ) in line 19.

For clarity, the vias 20, 21 and 22 as well as the electrodes 10, 13 and 14 are not shown in FIGS. 9 and 10.

It is important to specify that at each moment (each calculation step) the stacks are in equilibrium in the fields: the equilibrium is maintained so that the current is applied (i.e., during the operation of the circuit) and is lost as soon as the current is no longer applied.

What is meant next by the distance between a current line and a magnetoresistive stack is the distance separating the center of the soft layer and the point of the line closest to said center of the soft layer.

The current line 18 (of intermediate level of metallization N2) that we will call the “magnetic polarization line” is a line directed along the x axis and passing at the same time under the magnetoresistive stack MTJ1 and under the magnetoresistive stack MTJ2 at a distance d along the vertical z axis. Note that this current line 18 could also be above the MTJ1 and MTJ2 stacks at a same distance d and produce the same effect (with a current flowing therethrough in the opposite direction).

The current line 19 (from the upper level of metallization N3) is a line substantially in the form of a U having two parallel branches 23 and 24 along the y axis and which are situated above the MTJ1 and MTJ2 stacks at a double distance 2×d in relation to the distance d separating the line 18 from the MTJ1 and MTJ2 stacks.

The current line 17 (from the lower level of metallization N1) is a line along the y axis and is uniquely situated below the MTJ1 stack at a double distance 2×d in relation to the distance d separating the line 18 from the MTJ1 stack.

Moreover, the current line 17 is electrically connected to the current line 19 at its branch 24 through a vertical interconnection via 25 so that the currents of lines 17 and 19 are added before being routed over the branch 23 of the current line 19 producing its effects on stack MTJ2.

Consequently, for the first magnetoresistive stack MTJ1, lines 19 and 17 supplying currents I_{Cin} et I_{B} are on either side of the stack MTJ1 and equidistant from it while current line 18 supplying current I_{A} is under MTJ1 (or above) at a distance half as significant than the two other lines 19 and 17. Thus, for a given current I enabling a rotation of the magnetization of the soft layer of stack MTJ1 from the parallel state to the anti-parallel state, the field generated in the center of the soft layer by line 18 is two times more intense than the one generated by lines 19 and 17.

Concerning MTJ2, it is in the same configuration with respect to line 18 undergoing an influence identical to MTJ1; on the other hand, the currents of lines 17 and 19 are added (Kirchhoff's laws), this sum being routed over the branch of line 19 above the magnetoresistive stack MTJ2 at a double distance from that associated with line 18. Note that we could have also added the current of lines 17 and 19 and taken a line 17 in U and a line 19 situated uniquely above the MTJ1 stack. In this case, the sum of the current would have been routed over the branch of line 17 below the MTJ2 stack at a double distance from that associated with line 18.

We now evaluate the reaction of the sum generation magnetic part 3 with the various possible configurations. We will take the previously made assumptions. Thus, on input, we will consider that ‘0’ [symbol] −I and ‘1’ [symbol] I. Likewise, on output we will have:

ΔR=R_{MTJ1}−R_{MTJ2}>0 [symbol] S=‘1’ and,

ΔR=R_{MTJ1}−R_{MTJ2}<0 [symbol] =S=‘0’.

We will call R_{MTJi}^{p} the resistance of the magnetoresistive stack MTJi in its parallel or substantially parallel state and R_{MTJi}^{ap} the resistance of the MTJi stack in its anti-parallel or substantially anti-parallel state. We will call R_{MTJi}^{int} the resistance of the magnetoresistive stack MTJi in an intermediate state (θ including between 0 and π) between R_{MTJi}^{ap} and R_{MTJi}^{p} so that: R_{MTJi}^{ap}>R_{MTJi}^{int}>R_{MTJi}^{p}.

We can also write the magnetic field generation table seen by each one of the stacks MTJ1 and MTJ2 for the various combinations of the input vector A, B and Cᵢₙ. This table is shown in table 3 below:

TABLE 3

| A | B | Cᵢₙ | I_{A} | I_{B} | I_{CIN} | H_{MTJ1}^{x} | H_{MTJ1}^{y} | H_{MTJ2}^{x} | H_{MTJ2}^{y} |
|---|---|---|---|---|---|---|---|---|---|
| 0 | 0 | 0 | −I | −I | −I | $\frac{- H}{2} + \frac{H}{2} = 0$ | +H | $\frac{- 2 H}{2} = - H$ | +H |
| 0 | 0 | 1 | −I | −I | +I | $\frac{- 2 H}{2} = - H$ | +H | $\frac{- H}{2} + \frac{H}{2} = 0$ | +H |
| 0 | 1 | 0 | −I | +I | −I | $\frac{+ 2 H}{2} = + H$ | +H | $\frac{- H}{2} + \frac{H}{2} = 0$ | +H |
| 0 | 1 | 1 | −I | +I | +I | $\frac{H}{2} - \frac{H}{2} = 0$ | +H | $\frac{+ 2 H}{2} = + H$ | +H |
| 1 | 0 | 0 | +I | −I | −I | $\frac{- H}{2} + \frac{H}{2} = 0$ | −H | $\frac{- 2 H}{2} = - H$ | −H |
| 1 | 0 | 1 | +I | −I | +I | $\frac{- 2 H}{2} = - H$ | −H | $\frac{- H}{2} + \frac{H}{2} = 0$ | −H |
| 1 | 1 | 0 | +I | +I | −I | $\frac{+ 2 H}{2} = + H$ | −H | $\frac{- H}{2} + \frac{H}{2} = 0$ | −H |
| 1 | 1 | 1 | +I | +I | +I | $\frac{H}{2} - \frac{H}{2} = 0$ | −H | $\frac{+ 2 H}{2} = + H$ | −H |

H shows the intensity of the field generated in the vicinity of the soft layer by a current I flowing in a current line situated at a distance d from the center of the soft layer of the magnetoresistive stack MTJi. Consequently, for a line situated at a distance 2×d, the intensity of the generated field will be equal to H/2.

H_{MTJi}^{x} and H_{MTJi}^{y} shows the components along the x and y axes from the magnetic field vector generated in the vicinity of the soft layer of the MTJi stack.

We establish the values of the components H_{MTJi}^{x} and H_{MTJi}^{y} for the magnetoresistive stacks MTJ1 and MTJ2, according to the fields obtained, the final truth table yielding the resistive states of each one of the magnetoresistive stacks R_{MTJ1} et R_{MTJ2}, the sign of the resistance variation sgn (ΔR) (where sgn( ) designates the function sign) and the binary output value in the form of a voltage S generated by the output interface 4 shown in FIG. 7. This truth table is shown in table 4 below. The detection by the output interface is carried out in the field: it's the combination of the magnetic fields generated by each of the inputs and via the specific interconnection network for each one of the two magnetic parts 3 and 5 (carry, sum) which will stabilize the magnetic states during read time. It is thus preferable to use the rapid differential amplifiers not only enabling a weak adder propagation time (high speed calculation) but also an information maintenance time (“hold” time) on reduced input, decreasing the consumption so much more during the operation. Opting for a relatively weak nominal magnetoresistive stack resistance and a strong magnetoresistive tunnel (especially by using MgO) is a non-trivial advantage over the read speed (of strong relative and absolute currents decreasing the response time of the amplifier).

TABLE 4

| H_{MTJ1}^{x} | H_{MTJ1}^{y} | H_{MTJ2}^{x} | H_{MTJ2}^{y} | R_{MTJ1} | R_{MTJ2} | sgn(ΔR) | S |
|---|---|---|---|---|---|---|---|
| 0 | +H | −H | +H | R^{P} | R^{INT} | ΔR < 0 | 0 |
| −H | +H | 0 | +H | R^{INT} | R^{P} | ΔR > 0 | 1 |
| +H | +H | 0 | +H | R^{INT} | R^{P} | ΔR > 0 | 1 |
| 0 | +H | +H | +H | R^{P} | R^{INT} | ΔR < 0 | 0 |
| 0 | −H | −H | −H | R^{AP} | R^{INT} | ΔR > 0 | 1 |
| −H | −H | 0 | −H | R^{INT} | R^{AP} | ΔR < 0 | 0 |
| +H | −H | 0 | −H | R^{INT} | R^{AP} | ΔR < 0 | 0 |
| 0 | −H | +H | −H | R^{AP} | R^{INT} | ΔR > 0 | 1 |

We could see to it that the generated fields on the x axis (perpendicular to the magnetization of the hard layers) are more intense than the fields generated on the y axis to enable a good saturation of the soft layers in the considered direction and to maximize this the relative variation of resistance, or:

H_{MTJi}^{x}>H_{MTJi}^{y}

We obtain the sum S in accordance with the truth table of the Binary Full Adder FA given in table 2. We note that the currents of identical intensities crossing the conductors on either side of the magnetoresistive stack will generate the fields in the opposite directions if the currents are in the same direction and a maximum field if these currents are in opposite directions: this is the case of stack MTJ1. Concerning MTJ2, if the added currents are in opposite directions, the effect cancels itself out and the field generated is null; if they are in the same direction, the field is maximum.

The sum generation magnetic part 5 is comprised of:
a third magnetoresistive stack including a ferromagnetic hard layer and a ferromagnetic soft layer separated by a non-ferromagnetic interlayer.
a fourth magnetoresistive stack MTJ4 formed by a ferromagnetic hard layer and a ferromagnetic soft layer separated by a non-ferromagnetic interlayer.

As for the stacks MTJ1 and MTJ2, the various layers of the two magnetoresistive stacks MTJ3 and MTJ4 are not shown, for clarity. The ferromagnetic soft layer is created in a magnetically soft material such as Permalloy, for example. Its magnetization responds easily to the variations of an outside magnetic field which is applied. This layer is preferably fine enough so that its magnetization can turn in a significant fashion under the effect of weak magnetic flows. The ferromagnetic, hard layer presents a pinned magnetization. Moreover, the layer of the non-ferromagnetic interlayer may be made of MgO.

Preferably, the soft layers present a circular or semi-circular shape minimizing the write current necessary for the variation of their magnetic orientation.

The magnetizations of the hard layers of the two stacks MTJ3 and MTJ4 are positioned in the same direction as those of the stacks MTJ1 and MTJ2.

The MTJ3 and MTJ4 stacks are connected at their upper part by an upper common electrode 26 of polarization substantially directed along the y axis. This upper electrode is connected to the rail 12 of a positive voltage supply by a vertical conductive via 27.

The MTJ3 stack is connected at its lower part by a lower electrode 28 substantially directed along the y axis and connected to a vertical conductive via 29. This conductive via 29 supplies the current I3 forming the input of the output interface 5 illustrated in FIG. 5.

The MTJ4 stack is connected at its lower part by a lower electrode 30 substantially directed along the y axis and connected to a vertical conductive via 31. This conductive via 31 supplies the current I4 forming the input of the output interface 5 illustrated in FIG. 5.

The carry generation magnetic part 5 additionally includes a conductive line 32 belonging to the level of metallization N1 (same level as the conductive line 17). FIG. 11 shows a view of the carry generation magnetic part 5 in the xy plane (seen from above).

The MTJ3 and MTJ4 stacks are shown in the form of a solid hashed circle in FIG. 11 with a solid arrow symbolizing the magnetic orientation of the hard layer serving as reference.

The current line 32 is a line substantially in the form of a U having two parallel branches 33 and 34 along the x axis and which are situated below the MTJ3 and MTJ4 stacks at a distance identical to the distance separating current line 18 from the MTJ1 and MTJ2 stacks. The U form of current line 32 for a same direction of current generates opposite magnetic fields in each one of the stacks MTJ3 and MTJ4.

The carry generation magnetic part 5 moreover is comprised of two vertical conductor vias 35 and 36 electrically connecting the current line respectively to current line 18 through which the current I_{A} flows, and to the portion 23 of current line 19 through which the sum of currents I_{B}+I_{Cin} flows.

The sum of the three currents I_{A}+I_{B}+I_{Cin} thus flows in the current line 32 dedicated to the carry. As for the sum generation magnetic part 3, we can also write the magnetic field generation table seen by each one of the stacks MTJ3 and MTJ4 for the various combinations of the input vector A, B and Cᵢₙ. This table is shown in table 5 below:

TABLE 5

| A | B | Cᵢₙ | I_{A} | I_{B} | I_{CIN} | ΣI | H_{MTJ3} | H_{MTJ4} |
|---|---|---|---|---|---|---|---|---|
| 0 | 0 | 0 | −I | −I | −I | −3I | −3H | +3H |
| 0 | 0 | 1 | −I | −I | +I | −I | −H | +H |
| 0 | 1 | 0 | −I | +I | −I | −I | −H | +H |
| 0 | 1 | 1 | −I | +I | +I | +I | +H | −H |
| 1 | 0 | 0 | +I | −I | −I | −I | −H | +H |
| 1 | 0 | 1 | +I | −I | +I | +I | +H | −H |
| 1 | 1 | 0 | +I | +I | −I | +I | +H | −H |
| 1 | 1 | 1 | +I | +I | +I | +3I | +3H | −3H |

Contrary to the case of the magnetic part for which we could obtain three resistance values, the fields here are uniquely generated on the y axis relative to the magnetization of the hard layer so that we have either a resistance R_{MTJi}^{p} of the magnetoresistive stack MTJi in its parallel or substantially parallel state or a resistance R_{MTJi}^{ap} of the magnetoresistive stack MTJi in its anti-parallel or substantially anti-parallel state. H shows the intensity of the field generated in the vicinity of the soft layer by a current I flowing in a current line situated at a distance d from the center of the soft layer of the magnetoresistive stack MTJi.

We note that the current line 32 of the carry generation magnetic part 5 also includes a vertical conductive via 37 connected to the voltage supply Vdd/2 which will generate the bi-directional currents such as illustrated in FIG. 6.

We establish the values of the field for stacks MTJ3 and MTJ4 and according to the fields obtained, the final truth table yielding the resistive states of each of the stacks R_{MTJ3} et R_{MTJ4}, the sign of the resistance variation sgn (ΔR) (where sgn( ) designates the function sign and ΔR=R_{MTJ3}−R_{MTJ4}) and the binary value of the output in the form of a voltage Cₒᵤₜ generated by the output interface 6 shown in FIG. 5. This truth table is shown in table 6 below:

TABLE 6

| H_{MTJ3} | H_{MTJ4} | R_{MTJ3} | R_{MTJ4} | sgn (ΔR) | Cₒᵤₜ |
|---|---|---|---|---|---|
| −3H | +3H | R^{P} | R^{AP} | ΔR < 0 | 0 |
| −H | +H | R^{P} | R^{AP} | ΔR < 0 | 0 |
| −H | +H | R^{P} | R^{AP} | ΔR < 0 | 0 |
| +H | −H | R^{AP} | R^{P} | ΔR > 0 | 1 |
| −H | +H | R^{P} | R^{AP} | ΔR < 0 | 0 |
| +H | −H | R^{AP} | R^{P} | ΔR > 0 | 1 |
| +H | −H | R^{AP} | R^{P} | ΔR > 0 | 1 |
| +3H | −3H | R^{AP} | R^{P} | ΔR > 0 | 1 |

We obtain a carry Cₒᵤₜ in accordance with the truth table of the “Binary Full Adder” FA given in table 2. We note that the carry generation circuit 5 behaves as a majority voting circuit: indeed, the truth table of the adder shows that if the number of 0s on input is greater than the number of 1s, then the value of the carry is 0, and, conversely for 1, this operation being more difficult to perform in classical CMOS logic, the full circuit necessitating a significant number of transistors. Here, the sum of the bidirectional currents of identical intensities and a magnetic differential system calibrated to a rollover threshold of

$$\frac{H}{I}$$

easily performs this operation. Recall that a majority voting circuit is a component including a certain number of logic inputs and one logic output. This output is equal to “1” if the number of “1s” on input is greater than the number of “0s”. Note that according to this definition, such a device only has meaning if the number of inputs is odd. Table 7 shows the truth table of a majority voting circuit with three inputs.

TABLE 7

| a | b | C | Sv |
|---|---|---|---|
| 0 | 0 | 0 | 0 |
| 0 | 0 | 1 | 0 |
| 0 | 1 | 0 | 0 |
| 0 | 1 | 1 | 1 |
| 1 | 0 | 0 | 0 |
| 1 | 0 | 1 | 1 |
| 1 | 1 | 0 | 1 |
| 1 | 1 | 1 | 1 |

Comparing table 2 and table 7 and taking “a” equal to “A”, “b” equal to “B”, “c” equal to “Cᵢₙ” and “Sv” equal to “Cₒᵤₜ” we have the same truth table.

Thus, the invention combines the basic magnetic technology of magnetoresistive stack MTJ of first generation FIMS (for “Field Induced Magnetic Switching”, i.e., the magnetization of the soft layer modified by the application of a magnetically generated field by a current line in the vicinity of the magnetoresistive stack) with CMOS technology to perform a “Binary Full Adder” hybrid adder. This architecture is intended for applications of intense calculations needing relatively high performance, relatively low dynamic consumption and strong density integration.

The architecture of this adder thus includes 3 blocks, a first block made up of CMOS buffers dimensioned accordingly for enabling the generation of bidirectional currents injected in the interconnection system of the magnetic part. The bi-directionality is provided by a polarization of the routing lines with half the voltage supply of the circuit. Each of the inputs (A, B and Cᵢₙ) having relative equivalent weights in the addition calculation, the associated buffers will have equivalent sizes. The buffers thus drive three interconnection lines generating a current in each of them having direction which depends on the logic information applied on input. These lines cross the two magnetic structure differentials generating local fields according to the currents but also the routing topology. It is this topology that will “operationally” differentiate the magnetic sum generation parts and the output carry generation (the magnetic reactions of the two magnetic parts being different for a same stimulus). The use of a pair of magnetoresistive stacks operating in differential mode thereby benefits from the common-mode rejection of the read amplifiers and thus of a good immunity to the noise. We thus obtain a resistance variation ΔR “positive or negative” according to the direction of the local field applied and thus of the combination of the injected currents in the lines. This resistance variation is generated in the form of a CMOS stage differential current (differential amplifier) and converted in the form of a voltage in order to obtain the corresponding logic information, the sum for a block and the carry for the other, this one able to be transmitted to the next block for an n-bit calculation. We will see in what follows that it is also possible to transmit this information directly in the form of a current: we can, to some extent, abstain from “really calculating” the intermediate carries (i.e., regenerating these carries in the form of logic levels through the CMOS circuitry).

This architecture presents a certain number of advantages with respect to the equivalent CMOS circuits, the first being the dissociation between the circuits generating the input stimulus in current mode (the data to sum) and the generation circuits of the results, enabling the overall growth of system performance and limiting the dynamic power consumed during the calculations, this being so much more true with the magnetic structure differentials used necessitating relatively weak currents. We can consider that there is no contact between the emitter of the stimulus and the magnetic part: consequently, the calculation operation in itself practically does not consume power.

A second advantage is the dissociation between the calculation of the carry and that of the sum, the operations here being completely parallelized. Further, the magnetic and CMOS structures are completely identical, optimizing a simplification and a standardization (standard cell) of the performance process of such a component. This approach obtains a significant density for the CMOS part accentuated by the fact that the adder can use less than 20 transistors to operate (amplifiers+buffers).

Additionally, the development of the MRAM magnetic memories ensures the compatibility of the magnetic process with the standard CMOS process (digital environment). Consequently, the magnetic part can thus be added in post-processing above the CMOS part (“Above-IC). In this approach, the calculation is performed by the magnetic part with the help of weak variations (established by the combination of local fields) of the magnetizations of the stacks matched around the positions of equilibrium. This approach used in CMOS current mode logic (CML) for example is well adapted to the creation of rapid digital circuits, the functionality being set by the routing topology of the interconnections enabling a variation in power and in field direction. The CMOS part acts uniquely as an interface ensuring the compatibility of the circuit with the “classical” components.

Finally, a fourth advantage is the possibility of abstaining from calculating or in other terms, of regenerating the output carry in the form of a voltage, the read being the limiting factors (in terms of speed) of this architecture and of implicitly calculating this in the form of a current, directly in the corresponding input (Cᵢₙ) of the second adder. We can thus perform a 4-bit adder having the same overall speed as a 2-bit adder. When we look at tables 5 and 6, we realize that the sign of the sum of the currents flowing through current line 32 of the carry is completely correlated with the binary information output Cₒᵤₜ (carry generation by the CMOS output interface). This result is normal by construction, because when we want to perform an n-bit adder (it takes 32 “Binary Full Adders” to sum two 32-bit words), it is necessary to propagate the carry step by step. However, the intermediate carry calculations are not useful since only the sum and final carry are important. Consequently, we can, for example, create a 2-bit adder (sum of two 2-bit words) by cascading two binary full adders “Binary Full Adder” but by crossing the intermediate carry calculation, i.e., by reinjecting the current sum associated with the first stage carry directly in the input line of the second (we delete the intermediate output interface serving to regenerate the intermediate carry). This approach has the same calculation speed for 1-bit as for 2-bits. This approach may be generalized to an n-bit adder. The propagation time of an n-bit adder in accordance with the invention is on average divided by two. Further, in the case of a 2-bit adder, the latter only uses six MTJ stacks (the stacks associated with the carry calculation of the first stage being useless), three buffer amplifiers (such as the amplifier 304 in FIG. 7) and five interfaces (three input interfaces and two output interfaces). We thus decrease the overall size of the system and we lower the average consumption since the current from the first stage is used in the second.

This fourth advantage is illustrated by reference in FIG. 12 which represents a three dimensional view of a 2-bit adder 109 in accordance with the invention with carry propagation according to an xyz orthogonal reference frame. This adder 109 is comprised of a first sum generation magnetic part 103.

The first sum generation magnetic part 103 includes:

a first magnetoresistive stack MTJ1;

a second magnetoresistive stack MTJ2.

Note that the various magnetoresistives used in adder 109 are identical to those previously described in reference to adder 9 in FIG. 8.

The MTJ1 and MTJ2 stacks are connected at their upper part by an upper common electrode 110 of polarization substantially directed along the x axis. This upper electrode is connected to a rail 112 of positive voltage supply directed along the y axis by a vertical conductive via 111.

The MTJ1 stack is connected at its lower part by a lower electrode 114 connected to a vertical conductive via 116. This conductive via 116 supplies the current forming the first input of a first CMOS output interface such as that illustrated in FIGS. 5 and 7.

The MTJ1 stack is connected at its lower part by a lower electrode 113 connected to a vertical conductive via 115. This conductive via 115 supplies the current forming the second input of said first output interface such as illustrated in FIGS. 5 and 7.

The first output interface generates output signal S₀ such as illustrated in FIG. 4.

The magnetic circuit 109 is formed by three levels of metallization N1 to N3 (identical to those described in reference to FIG. 8) which will enable injecting:
the input currents I_{A0} (corresponding to the bit A₀ such as shown in FIG. 4), I_{B0} (corresponding to the bit B₀ to sum with A₀) and I_{Cin} (corresponding to the carry of input Cᵢₙ₀ such as shown in FIG. 4) transmitted by a first CMOS input interlace such as illustrated in FIG. 6.
the input currents I_{A1} (corresponding to the bit A₁ such as shown in FIG. 4) and I_{B1} (corresponding to the bit B₁ to sum with A₁) transmitted by a second CMOS input interface such as illustrated in FIG. 6 (we note here that the input interface does not supply the corresponding current to the carry Cₒᵤₜ₀ (or Cᵢₙ₁) since the latter will be propagated directly in the form of the magnetic circuit).

The first sum generation magnetic part 103 includes three conductive lines 117, 118, 119 belonging to the levels of metallization N1, N2 and N3 respectively.

Three vertical conductive vias 120, 121 and 122 with access to the CMOS input interface are electrically connected to the lines 117, 118 and 119 respectively.

The vertical via 120 thereby injects the current I_{B0} equaling +/−I in the line 117. The vertical via 121 thereby injects the current I_{A0} equaling +/−I in the line 118. The vertical via 122 thereby injects the current I_{Cin0} equaling +/−I in the line 119.

The current line 118 (of intermediate level of metallization N2) is a line directed along the x axis and at the same time passing under the MTJ1 stack and under the MTJ2 stack to a distance d along the vertical z axis. Note that this current line 118 could also be above the MTJ1 and MTJ2 stacks at a same distance d and produce the same effect (with a current flowing therethrough in the opposite direction).

The current line 119 (from the upper level of metallization N3) is a line substantially in the form of a U having two parallel branches 123 and 124 along the y axis and which are situated above the MTJ1 and MTJ2 stacks at a double distance 2×d in relation to the distance d separating the line 18 from the MTJ1 and MTJ2 stacks.

The current line 117 (from the lower level of metallization N1) is a line along the y axis and is uniquely situated below the MTJ1 stack at a double distance 2×d in relation to the distance d separating the line 118 from the MTJ1 stack.

Moreover, the current line 117 is electrically connected to the current line 119 at its branch 124 through a vertical interconnection via 125 so that the currents of lines 117 and 119 are added before being routed over the branch 123 of the current line 119 producing its effects on stack MTJ2.

The adder 109 includes a second sum generation magnetic part 403.

The second sum generation magnetic part 403 is structurally identical to the first sum generation magnetic part.

The second sum generation magnetic part 403 is comprised of:

a third magnetoresistive stack MTJ1′;

a fourth magnetoresistive stack MTJ2′.

The MTJ1′ and MTJ2′ stacks are connected at their upper part by an upper common electrode 410 of polarization substantially directed along the x axis. This upper electrode is connected to the rail 112 of positive voltage supply along the y axis by a vertical conductive via 411.

The MTJ1′ stack is connected at its lower part by a lower electrode 414 connected to a vertical conductive via 416. This conductive via 416 supplies the current forming the first input of a second CMOS output interface such as that illustrated in FIGS. 5 and 7.

The MTJ2′ stack is connected at its lower part by a lower electrode 413 connected to a vertical conductive via 415. This conductive via 415 supplies the current forming the second input of said second output interface such as illustrated in FIGS. 5 and 7.

The second output interface generates output signal S₁ such as illustrated in FIG. 4.

The second sum generation magnetic part 403 includes three conductive lines 417, 418, 419 belonging to the levels of metallization N1, N2 and N3 respectively.

Two vertical conductive vias 420 and 421 with access to the second CMOS input interface are electrically connected to the lines 417 and 418 respectively.

The vertical via 420 thereby injects the current I_{B1} equaling +/−I in the line 417. The vertical via 421 thereby injects the current I_{A1} equaling +/−I in the line 418.

The second sum generation magnetic part 403 additionally includes a vertical via 422 enabling the injection of a current of intermediate carry to which we will return to next. The vertical via 422 is electrically connected to the current line 419 at its branch 424.

The current line 418 (of intermediate level of metallization N2) is a line directed along the x axis and at the same time passing under the MTJ1′ stack and under the MTJ2′ stack to a distance d along the vertical z axis.

The current line 419 (from the upper level of metallization N3) is a line substantially in the form of a U having two parallel branches 423 and 424 along the y axis and which are situated above the MTJ1 and MTJ2 stacks at a double distance 2×d in relation to the distance d separating the line 418 from the MTJ1 and MTJ2 stacks.

The current line 417 (from the lower level of metallization N1) is a line along the y axis and is uniquely situated below the MTJ1 magnetoresistive stack at a double distance 2×d in relation to the distance d separating the line 418 from the MTJ1 stack.

Moreover, the current line 417 is electrically connected to the current line 419 at its branch 424 through a vertical interconnection via 425 so that the currents of lines 417 and 419 are added before being routed over the branch 423 of the current line 419 producing its effects on stack MTJ2′.

Moreover, adder 109 is comprised of a current line 132 of carry propagation belonging to the level of metallization N1 and two vertical conductor vias 135 and 136 electrically connecting the current line 132 respectively to the current line 118 through which current I_{A0} flows and to the portion 123 of current line 119 through which the sum of currents I_{B0}+I_{Cin0} flows.

The sum of the three currents I_{A0}+I_{B0}+I_{Cin0} flows thus in the current line 132 dedicated to the propagated carry. Contrary to the line 32 of the 1-bit adder from FIG. 8, this line 132 does not serve to produce a magnetic field on two magnetoresistive stacks but simply to propagate the intermediate carry in the form of a current without regenerating in the form of a compatible CMOS voltage: here we save an output interface as well as two stacks.

The current line 132 is then prolonged up to vertical conductive via 422 to supply the input in current Iᵢₙₜ₀ of this latter.

Adder 109 is comprised of a final carry generation magnetic part 405.

This final carry generation magnetic part 405 is structurally identical to the carry generation magnetic part 5 such as shown in FIG. 8. It includes:
a fifth magnetoresistive stack MTJ3′;
a sixth magnetoresistive stack MTJ4′.

The MTJ3′ and MTJ4′ stacks are connected at their upper part by an upper common electrode 426 of polarization substantially directed along the y axis. This upper electrode is connected to the rail 112 of a positive voltage supply by a vertical conductive via 427.

The MTJ3′ stack is connected at its lower part by a lower electrode 428 substantially directed along the y axis and connected to a vertical conductive via 429. This conductive via 429 supplies the current forming the input of the third output interface such as illustrated in FIG. 5.

The MTJ4′ magnetoresistive stack is connected at its lower part by a lower electrode 430 substantially directed along the y axis and connected to a vertical conductive via 431. This conductive via 431 supplies the current forming the input of the third output interface such as illustrated in FIG. 5.

The final carry generation magnetic part 405 includes a conductive line 432 belonging to the level of metallization N1 (same level as the conductive line 417).

The current line 432 is a line substantially in the form of a U having two parallel branches 433 and 434 along the x axis and which are situated below the MTJ3′ and MTJ4′ stacks respectively at a distance d identical to the distance separating current line 418 from the MTJ1′ and MTJ2′ stacks. The U form of the current line 432 for a same direction of current generates opposite magnetic fields in each one of the stacks MTJ3′ and MTJ4′.

We note that the current line 432 of the carry generation magnetic part 405 also includes a vertical conductive via 437 connected to the voltage supply Vdd/2 which will generate the bi-directional currents such as illustrated in FIG. 6.

Moreover, the final carry magnetic part 405 is comprised of two vertical conductor vias 435 and 436 electrically connecting the current line 432 to the current line 418 respectively through which the current I_{A1} flows and the portion 423 of the current line 419 through which the sum of the currents I_{B1}+Iᵢₙₜ₀ flows.

The sum of the three currents I_{A1}+I_{B1}+Iᵢₙₜ₀ flows thus in the current line 432 dedicated to the carry.

Moreover, adder 109 includes a vertical via 438 electrically connected to the current line of carry propagation 132: we will return in what follows to the use of this via 438.

The approach proposed above assumes, however, limiting the current Iᵢₙₜ₀ to inject in the conductive via 422 to I in absolute value; yet this value is exceeded by the vectors (A₀ B₀ Cin₀) equaling 000 and 111. When the input vector is 000, the sum of the injected currents is −3×l and when the input vector is 111 the sum of the injected currents is 3×l. To solve this problem, we could use the CMOS limiting circuit 500 such as illustrated in FIG. 13 to regulate the current from the input vector, an action which is not penalized by the performances regarding the response time of the amplifiers on the magnetic parts which can be relatively long.

The CMOS limiting circuit 500 includes:
three PMOS transistors 501, 502, and 503 mounted in series, the source of the first PMOS transistor 501 being connected to the positive voltage supply;
three NMOS transistors 504, 505, and 506 mounted in series, the source of the third NMOS transistor 506 being connected to the ground;

The six PMOS and NMOS transistors are mounted in series so that the drain of the first NMOS transistor 504 is connected to the drain of the third PMOS transistor 503.

The first PMOS transistor 501 and the third NMOS transistor 506 have their common gate on which signal A₀ is injected.

The second PMOS transistor 502 and the second NMOS transistor 505 have their common gate on which signal B₀ is injected.

The third PMOS transistor 503 and the first NMOS transistor 504 have their common gate on which signal Cᵢₙ₀ is injected.

The common drain from the first NMOS transistor 504 and the third PMOS transistor 503 is connected to the current line 132 of the carry propagation by the vertical conductive via 438 (also shown in FIG. 12).

As already stated above, each current line is connected to the voltage source Vdd/2 (by the conductive via 437) so that it is able to transmit a bidirectional current.

When the vector is 000, the sum of the injected currents in the line 132 is −3×l; the regulator 500 injects a current 2×l in the via 438 (activation of the PMOS transistors 501 to 503) to regulate the current to −1, conserving the sign in the same time. In the same way, if the vector is 111, the sum of the injected currents is +3×l; the regulator injects −2×l in the via 438 (activation of the NMOS 504 to 506) in order to regulate the current to +l. Thus we still have a current equal to +/−l in the branch of the current line 132 situated after the regulator 500. Regarding the architecture of the regulator, the other combinations of the input vector do not have any effect on the current.

Of course, the invention is not limited to the mode of operation which was just described.

Notably, the invention has been more particularly described in the case of a 1 or 2 bit adder but it has other uses in the generation of other types of logic functions.

As an example, in what follows we will present a device for the creation of logical “and” gate in accordance with the invention from a field write-in magnetoresistive stack by using the distance between the write lines and the stack to vary the magnetic fields generated before summing them. A two input “and” gate gives the logical value “1” in output if and only if all its inputs are at “1”. This is rendered by the truth table given in table 8 below.

TABLE 8

| A | | |
|---|---|---|
| B | 0 | 1 |
| 0 | 0 | 0 |
| 1 | 0 | 1 |

As previously, the A and B inputs are encoded in current so that:

A=‘0’ [symbol] I_{A}=−I

A=‘1’ [symbol] I_{A}=I

B=‘0’ [symbol] I_{B}=−I

B=‘1’ [symbol] I_{B}=I

Thus, currents I_{A} et I_{B} will be negative in the case where the information is ‘0’ and positive in the case where the information is ‘1’.

FIGS. 14 a) and b) schematically represent a device 600 for the creation of a logical “and” gate seen from above (xy plane) and a lateral cross-section (along the zy plane), respectively.

The device 600 is comprised of:
a magnetoresistive stack including a ferromagnetic hard layer and a ferromagnetic soft layer separated by an non-ferromagnetic interlayer (the characteristics of this stack are identical to those previously described in reference to the other operation modes of the invention).
a first current line 601 receiving current I_{A} belonging to a first level of metallization;
a second current line 602 receiving current I_{B} belonging to a second level of metallization;
a third current line 603 belonging to a third level of metallization;

The absolute value of the current is always the same (equal to I). The state of the magnetoresistive stack MTJ represents the output of the “and” gate: the parallel state of the magnetoresistive stack represents a “1”, the anti-parallel state a “0”. The arrows of current represent the directions in which the current is positively counted. With the conventions used, a positive current generates a positive field along the x axis.

As already mentioned above, we mean by the distance between a current line and a magnetoresistive stack the distance separating the center of the soft layer and the point of the line closest to center of the soft layer.

The third current line 603 (of intermediate level of metallization) is a line directed along the y axis and passing above the MTJ stack to a distance d along the vertical z axis. Note that this current line 603 could also be below the MTJ1 stack at a same distance d and produce the same effect (with a current flowing therethrough in the opposite direction).

The current line 601 (from the upper level of metallization) is a line directed along the y axis and is situated above the MTJ stack at a double distance 2×d in relation to the distance d separating the line 603 from the MTJ stack.

The second current line 602 (from the lower level of metallization) is a line along the y axis and is situated below the MTJ stack at a double distance 2×d in relation to the distance d separating the line 603 from the MTJ stack.

In this device 600, the line 603 is an additional line necessary to break the symmetry of the device: indeed, if we only have the lines corresponding to the A and B inputs (601 and 602) and we reverse the value of the inputs, the magnetic state will inevitably be opposite. Thus we cannot have the same output configuration for the “01” and “10” combinations of the inputs as this is the case for an “and” gate. By using this line 603 of additional current having a current flow of constant value, we bring a dissymmetry in the form of a field shift. This line 603 always has a negative current flow with a value of −I. The distance between the lines and the stack varies the impact of a current: for a same current I, the field generated is two times stronger if the distance d is two times smaller. The magnetic state of the magnetoresistive stack and therefore the output value according to the values of the inputs are given in table 9 below. The “and” function is created.

TABLE 9

| A | B | Iₐ | I_{b} | I | H₁^{a} | H₁^{b} | H₆₀₃ | Hₜₒₜ | State | Output |
|---|---|---|---|---|---|---|---|---|---|---|
| 0 | 0 | −I | −I | −I | −H | −2H | −2H | −5H | AP | 0 |
| 0 | 1 | −I | I | −I | −H | 2H | −2H | −H | AP | 0 |
| 1 | 0 | I | −I | −I | H | −2H | −2H | −3H | AP | 0 |
| 1 | 1 | I | I | −I | H | 2H | −2H | H | P | 1 |

where H₁^{a} designates the field generated by the line 601;
H₁^{b} designates the field generated by the line 602;
H₆₀₃b designates the field generated by the line 603;
Hₜₒₜ designates the total field generated by the three lines 601, 602 and 603;

We mentioned in table 9 two stable states of electrical resistance of the MTJ stack: either a parallel state P or an anti-parallel state for the electrical resistance of the MTJ stack. However, it is not necessary to have a stable junction. The choice of an unstable junction can even prove to be advantageous since this will react more easily in the magnetic field, improving speed and consumption. Recall that the electrical resistance of the MTJ stack is given in first approximation (weak bias voltage and ambient temperature) by the relationship:

R_{MTJ}=Rₚ.(1+TMR.(1−cos θ)/2)

where:
Rₚ. is the nominal resistance of the magnetoresistive stack when the magnetizations of the two layers of the stack are oriented in the same direction;
TMR represents the magnetoresistance tunnel, i.e., the relative variation of resistance between the extreme orientation states;
θ is the angle formed between the orientations of the hard and soft layers.

Thus, when θ equals 0, the magnetoresistive stack is in a parallel state where the stack resistance in its parallel state R^{p} reaches its minimum and equals R_{MTJ}^{p}=Rₚ, whereas when θ=π, the magnetoresistive stack is in an anti-parallel state and the electrical resistance of the stack in its anti-parallel state R_{MTJ}^{ap} is maximum and equals R_{MTJ}^{ap}=Rₚ.(1+TMR).

In a memory approach (therefore different from the invention) the information is stored in a non-volatile way. It is therefore necessary that the junction have a significant stability. This stability can be obtained in several ways, by increasing the shape anisotropy, for example. In a classical use of memory, the stack is thus oval with a large shape factor. The easy magnetization axis is directed along the large axis of the junction. In this approach, the field is applied in a manner moves the magnetism from its position of equilibrium sufficiently so that when the field is no longer applied the magnetization returns to its second stable position and conserves it (bi-stable operation). The information is thus conserved outside of any external solicitation, hence the non-volatile character. We will speak therefore in this case of the “switching” of the magnetization. In this case, the magnetization of the hard layer is aligned with this easy magnetization axis so as to switch between the Parallel and Anti-Parallel states to benefit from a maximum TMR.

In the approach concerned by this invention, the memory effect is not sought: the information must just be maintained during the calculation, i.e., when the field is applied. Here, the stability is thus provided by the magnetic field applied during operation. However, it is not necessary to have a stable junction. The choice of an unstable junction can even prove to be advantageous since this will react more easily in the magnetic field, improving speed and consumption.

In order to reduce the stability of the junction, we can use round, or almost round, stack values (with a form factor of little significance). The soft layer conserves an easy magnetization axis of the magneto-crystalline anisotropy. The application of a magnetic field in this case will not flip the magnetization of the soft layer between two stable states, but move the magnetization away from its stable position of an angle θ, positive or negative according the information encoded (‘0’ or ‘1’). In order to differentiate this operation from the memory operation previously described, we will speak of “modulation” or magnetization rather than “switching”. In this case, the magnetization of the hard layer must be perpendicular to the easy magnetization axis so that the magnetization of the soft layer approaches the Parallel or Anti-Parallel state.

According to this approach, it is thus the sign of the angle which will represent the binary value ‘0’ or ‘1’. Whatever the initial stable position, the operation remains perfectly symmetrical. The choice of the absolute value of θ will also enable choosing between speed and consumption: a small angle θ will need a slight magnetic field, but the signal will be less significant slowing the CMOS readout circuitry. A more significant angle will increase the readout speed.

In accordance with the invention, this is the three dimensional topology of the magnetic parts and the write lines which form the logic function.

This approach thereby avoids the use of the intermediate CMOS parts of the component, not being broken down in elementary blocks of “and”, “or” or “not”.

The CMOS parts are only used to create the input and output interfaces of the function. This frees the response time inherent in a CMOS technology and enables the full benefit of the qualities of the magnetic components in terms of speed and consumption.

1. A device for performing a “logic function” including a magnetic structure comprising:
at least one first magnetoresistive stack including a first ferromagnetic layer and a second ferromagnetic layer separated by a non-ferromagnetic interlayer; and
at least one first and one second current line belonging to a first and a second level of metallization respectively, each of said two lines generating a magnetic field in the vicinity of said first magnetoresistive stack when an electrical current flows therethrough,
wherein, for said at least one first magnetoresistive stack, said first and second lines are disposed at various distances from said second ferromagnetic layer, said various distances being determined by said “logic function”.

2. A device according to claim 1 wherein, for said at least one magnetoresistive stack, said first and second lines are situated on either side of said magnetoresistive stack.

3. A device according to claim 1, wherein said first line is situated at a distance d1 above said second layer and said second line is situated at a distance d2 below said second layer, so that, for two currents of the same intensity flowing in said first line and said second line respectively, the intensities H1 and H2 of the fields generated by said first and second lines respectively in the vicinity of said second layer are such that:
$$\frac{{H}_{1}}{{H}_{2}} = \frac{{d}_{2}}{{d}_{1}}$$

4. A device according to claim 1, comprising:
at least one magnetoresistive stack including a first ferromagnetic layer and a second ferromagnetic layer separated by a non-ferromagnetic interlayer;
at least one first and one second current line belonging to a first and a second level of metallization respectively, each of said two lines generating a magnetic field in the vicinity of said at least one first stack when an electrical current flows through them,
said first and second lines being disposed at equal distance on both sides of said second ferromagnetic layer.

5. A device according to claim 1, wherein said magnetic structure includes:
a second magnetoresistive stack which can be either merged with said first stack or different from said first stack, said second stack, said second magnetoresistive stack including a first ferromagnetic layer and a second ferromagnetic layer separated by a non-ferromagnetic interlayer,
a current line situated in the vicinity of said second magnetoresistive stack and generating a magnetic field in the vicinity of said second stack when an electrical current flows therethrough, said third line comprising at least two current input points so that two currents add in said line.

6. A device according to claim 5, wherein said line situated in the vicinity of said second magnetoresistive stack is connected to at least one other current line belonging to a level of metallization different from the level of metallization of said line situated in the vicinity of said second magnetoresistive stack, the two lines being connected by an interconnection conductive line and the point of connection between said interconnection line and said line situated in the vicinity of said second magnetoresistive stack forming one of said two current input points.

7. A device according to claim 5, wherein said at least two current input points inject a current I1 and I2 respectively in said line situated in the vicinity of said second magnetoresistive stack so that the intensity H′ of the field generated by said third line in the vicinity of said soft layer is such that
$$\frac{{H}^{′}}{H} = \frac{{I}_{1} + {I}_{2}}{I}$$
where H is the intensity of the magnetic field generated by said current line situated in the vicinity of said second magnetoresistive stack when a current I flows therethrough.

8. A device according to claim 1, wherein the first ferromagnetic layer is a ferromagnetic hard layer pinned in a fixed magnetic state which serves as a reference and the second ferromagnetic layer is a ferromagnetic soft layer.

9. A device according to claim 8, wherein the soft layer presents a circular or semi-circular shape minimizing the write current necessary for the variation of their magnetic orientation.

10. A device according to claim 8, wherein the hard layer of each of the magnetoresistive stacks is pinned in a magnetic state perpendicular to an axis of easy magnetization used as a reference for the soft layer of the same stack, with the soft layer of the magnetoresistive stack having a magnetic orientation that can be modulated by the current coming from the current line or current lines situated in the vicinity of the magnetoresistive stack so as to induce a modification to the transversal resistance of the stack sufficient to set off an electric signal, with such modulation of the magnetic orientation of the layer being sufficiently weak so that the orientation does not switch between two stable positions but fluctuates around one stable position.

11. A device according to claim 1, comprising an input interface comprised of:
at least one input receiving logic information encoded in the form of a voltage level representing a logical ‘0’ or ‘1’;
at least one output connected to an interconnection conductive line;
electronic means for generating a current in said interconnection conductive line having a direction representative of the logic information, the absolute value of the intensity of said current being identical in either direction of said current.

12. A device according to claim 1, comprising an electrically connected output interface to said at least one first magnetoresistive stack, said interface comprising:
a current input connected to an interconnection conductive line electrically connecting said current input to said at least magnetoresistive stack;
means for measuring the current flowing in said at least one first stack, the current representative of the magnetic state of said at least first stack;
means for generating a voltage representative of said magnetic state according to said current.

13. A device according to claim 1, comprising:
a second magnetoresistive stack including a first ferromagnetic layer and a second ferromagnetic layer separated by a non-ferromagnetic interlayer;
an output interface electrically connected to said first and second magnetoresistive stacks, said interface comprising:
a first current input connected to an interconnection conductive line electrically connecting said first current input to said first magnetoresistive stack;
a second current input connected to an interconnection conductive line electrically connecting said second input to said second magnetoresistive stack;
means for generating a differential current (Δi_{read}) between the current flowing in said first stack and the current flowing in said second stack when they are subjected to a bias voltage, said differential current being representative of a logic information;
means for generating a voltage representative of said logic information according to said current differential.

14. A device according to claim 11, wherein said input and/or output interface is performed in CMOS technology.

15. A device according to claim 14, wherein said magnetic structure is situated above said interfaces performed in CMOS technology.

16. A device according to claim 1, wherein the non-ferromagnetic interlayer junction is made of magnesium oxide MgO.

17. A device according to claim 1, comprising at least two lines of different widths situated in the vicinity of a magnetoresistive stack.

18. An adder incorporating a device according to claim 1, said adder comprising:
a current input interface of current signals I_{A}, I_{B} and I_{Cin} magnetizing three interconnection lines,
a magnetic structure comprising:
a generation magnetic part of a sum,
a generation magnetic part of a carry,
said generation magnetic part of said sum comprising:
a first magnetoresistive stack including a ferromagnetic hard layer and a ferromagnetic soft layer separated by an non-ferromagnetic interlayer, the ferromagnetic hard layer being pinned in a fixed magnetic state which serves as reference;
a second magnetoresistive stack including a ferromagnetic hard layer and a ferromagnetic soft layer separated by an non-ferromagnetic interlayer, the ferromagnetic hard layer being pinned in a fixed magnetic state which serves as reference;
a first, second and third current line belonging to a first, second and a third level of metallization respectively,
a first, a second and a third vertical conductive via with access to said current input interface electrically connected to said first, second and third current lines respectively so that the first vertical via injects current I_{B} in said first line, said second vertical via injects current I_{A} in said second line and said third vertical via injects current I_{Cin} in said third line,
said second current line generating a magnetic field in the vicinity of said first and second stack and being situated at a distance d along the vertical axis of the soft layers of each one of said first and second stack.
said first current line generating a magnetic field in the vicinity of said first stack and being situated at a distance 2×d along the vertical axis of the soft layer of said first stack,
said third current line generating a magnetic field in the vicinity of said first and second stack and being situated at a distance 2×d along the vertical axis of the soft layers of each one of said first and second stack,
said first current line being electrically connected to said third current line through a vertical interconnection via so that the currents I_{B} and I_{Cin} of said first and third lines are added before being routed over the branch of said third current line generating a magnetic field in the vicinity of said second stack, and
said second current line being substantially perpendicular to said first and third current lines in the vicinity of said first stack and said second current line being substantially perpendicular to said third current line in the vicinity of said second stack.

19. An adder according to claim 18, wherein said carry generation magnetic part comprises:
a third magnetoresistive stack including a ferromagnetic hard layer and a ferromagnetic soft layer separated by a non-ferromagnetic interlayer, the ferromagnetic hard layer being pinned in a fixed magnetic state which serves as reference;
a fourth magnetoresistive stack including a ferromagnetic hard layer and a ferromagnetic soft layer separated by an non-ferromagnetic interlayer, the ferromagnetic hard layer being pinned in a fixed magnetic state which serves as reference;
a fourth current line belonging to said first level of metallization, said fourth current line generating a magnetic field in the vicinity of said third and fourth stack and being situated at distance d along the vertical axis of the soft layers of each of said third and fourth stacks,
a fourth and fifth vertical conductive via electrically connecting said fourth current line to said second current line respectively in which current I_{A} flows, and to said branch of said third current line in which the sum of currents I_{B}+I_{Cin} flows, so that the currents I_{B}+I_{Cin} and I_{A} are added before being routed over said fourth current line generating a magnetic field in the vicinity of said third and fourth stacks.

20. An adder according to claim 18, wherein said magnetic structure includes:
a fourth current line, referred to as a carry-propagation line, belonging to said first level of metallization,
a fourth and fifth vertical conductive via electrically connecting said fourth current line to said second current line respectively in which current I_{A} flows, and to said branch of said third, current line in which the sum of currents I_{B}+I_{Cin} flows, so that the currents I_{B}+I_{Cin} and I_{A} are added before being routed over said fourth current line,
a fifth current line belonging to a level of metallization different from said first level of metallization and suitable for producing a magnetic field in the vicinity of a magnetoresistive stack,
a sixth vertical conductive via electrically connecting said fourth current line to said fifth current line.

21. An adder according to claim 20, comprising:
a seventh vertical conductive via electrically connected to said carry-propagation line;
a limiting circuit for limiting the absolute value of the current flowing in said carry-propagation line, said limiting circuit being connected to said propagation line by said seventh conductive via.

22. An adder according to claim 21, wherein characterized in that said limiting circuit includes three PMOS transistors and three NMOS transistors mounted in series, the first PMOS transistor and the third NMOS transistor having a common gate, the second PMOS transistor and the second NMOS transistor having a common gate, the third PMOS transistor and the first NMOS transistor having a common gate, the common drain of the first NMOS transistor and the third PMOS transistor being connected to said carry-propagation line by said seventh vertical conductive via.

23. A logical “and” gate incorporating a device according to claim 1, said “and” gate comprising:
an input interface of current signals I_{A} and I_{B},
a magnetic structure comprising:
a magnetoresistive stack including a ferromagnetic hard layer and a ferromagnetic soft layer separated by an non-ferromagnetic interlayer, the ferromagnetic hard layer being pinned in a fixed magnetic state which serves as reference;
a first, second and third current line belonging to a first, second and a third level of metallization respectively,
said second current line receiving a predetermined constant current generating a magnetic field in the vicinity of said stack and being situated a distance d along a vertical axis of the second layer of said stack,
said first current line receiving current I_{A} generating a magnetic field in the vicinity of said stack and being situated at a distance 2×d along the vertical axis above the second layer of said stack,
said third current line receiving current I_{B} generating a magnetic field in the vicinity of said stack and being situated at a distance 2×d along the vertical axis below the second layer of said stack.
